(19) United States
(12) Patent Application Publication
(10) Pub. No.: US 2023/0255076 A1
(43) Pub. Date: Aug. 10, 2023

(54) DISPLAY DEVICE

(71) Applicant: SHARP KABUSHIKI KAISHA, Sakai City, Osaka (JP)

(72) Inventors: TOHRU OKABE, Sakai City, Osaka (JP); SHOJI OKAZAKI, Sakai City, Osaka (JP); SHINSUKE SAIDA, Sakai City, Osaka (JP); SHINJI ICHIKAWA, Sakai City, Osaka (JP)

(21) Appl. No.: 18/015,186

(22) PCT Filed: Jul. 20, 2020
(86) PCT No.: PCT/JP2020/028122

§ 371 Date: Jan. 9, 2023

(51) Int. Cl. H10K 59/131; H10K 59/80

(52) U.S. Cl. CPC H10K 59/1315; H10K 59/871

(57) ABSTRACT

A thin-film transistor layer includes: a first wiring layer; a first planarization film; a second wiring layer; and a second planarization film, all of which are stacked on top of another in a stated order. The first planarization film and the second planarization film include a first slit shaped into a frame, provided between the display region and the first dam wall, and penetrating the first planarization film and the second planarization film. In the first slit, a first frame wire and a second frame wire have respective edge portions facing each other and covered with a protective film made of an inorganic insulating film included in the thin-film transistor layer.

### TECHNICAL FIELD

The present invention relates to a display device.

### BACKGROUND ART

In recent years, light-emitting organic electroluminescence (EL) display devices using organic EL elements are drawing attention as a replacement for liquid crystal display devices. Here, in order to reduce deterioration of the organic EL elements caused by such contaminants as water and oxygen, a sealing structure is suggested for the organic EL display devices. In the sealing structure, a sealing film to cover the organic EL elements is made of a multilayer film including an inorganic film and an organic film.

For example, Patent Document 1 discloses a display device including a thin-film sealing layer to cover organic light-emitting elements. The thin-film sealing layer has a multilayer structure in which an inorganic film layer formed by such a technique as chemical vapor deposition (CVD) and an organic film layer formed by such a technique as ink-jet printing are alternately arranged.

### CITATION LIST

### Patent Literature

Patent Document 1: Japanese Unexamined Patent Application Publication No. 2014-086415

### SUMMARY OF INVENTION

### Technical Problems

As seen in the display device disclosed in Patent Document 1 above, if the organic film of the sealing film is formed by ink-jet printing, a dam wall has to be provided to a frame region around a display region including the organic EL elements, in order to block ink that forms the organic film. Moreover, the organic EL display device includes, for example, a resin substrate, a thin-film-transistor (hereinafter also referred to as “TFT”) layer provided on the resin substrate, and an organic-EL-element layer provided on the TFT layer. Here, the TFT layer includes a frame wire provided to the frame region, and a planarization film having a flat surface in the display region and provided on the frame wire. Moreover, the organic-EL-element layer includes, for example, a plurality of first electrodes, an edge cover, a plurality of organic EL layers, and a second electrode, all of which are provided above the planarization film on top of another in the stated order. Then, if the dam wall is formed of the same material as, and in the same layer as, the planarization film is, a developer to be used for forming the planarization film, an etchant to be used for forming the first electrodes, and a developer to be used for forming the edge cover cause damage to the frame wire. Thus, for example, an end portion of the frame wire in cross-section is inevitably shaped into a peak. The peak reduces sealing capability of the sealing film to be formed on the frame wire, which might cause deterioration of the organic EL elements.

In view of the above problems, the present invention is intended to reduce damage to a frame wire during a production step of the frame wire.

### Solution to Problems

In order to achieve the above object, a display device according to the present invention includes: a base substrate; a thin-film-transistor layer provided on the base substrate, and including a first wiring layer, a first planarization film, a second wiring layer, and a second planarization film, all of which are stacked on top of another in a stated order; a light-emitting-element layer provided on the thin-film-transistor layer, and including a plurality of first electrodes, an edge cover, a plurality of light-emitting layers, and a second electrode, all of which are stacked on top of another in a stated order, each of the plurality of first electrodes and each of the plurality of light-emitting layers corresponding to one of a plurality of sub-pixels included in a display region, and the edge cover and the second electrode being provided in common among the plurality of sub-pixels; a sealing film provided to cover the light-emitting-element layer, and including a first inorganic sealing film, an organic sealing film, and a second inorganic sealing film, all of which are stacked on top of another in a stated order; a first dam wall provided in a frame region around the display region and surrounding the display region, the first dam wall being shaped into a frame to overlap with a peripheral end portion of the organic sealing film; a power supply line provided in the display region and serving as the second wiring layer; a first frame wire provided in the frame region and serving as the first wiring layer, the first frame wire extending to a terminal unit at an end portion of the frame region and being electrically connected to the power supply line; and a second frame wire provided in the frame region and serving as the first wiring layer, the second frame wire extending to the terminal unit and being electrically connected to the second electrode through a conductive layer formed of a same material as, and in a same layer as, each of the first electrodes is. The first planarization film and the second planarization film include a first slit shaped into a frame, provided between the display region and the first dam wall, and penetrating the first planarization film and the second planarization film. In the first slit, the first frame wire and the second frame wire have respective edge portions facing each other and covered with a protective film made of an inorganic insulating film included in the thin-film transistor layer.

### Advantageous Effect of Invention

The present invention can reduce damage to a frame wire during a production step of the frame wire.

### BRIEF DESCRIPTION OF DRAWINGS

FIG. 1 is a plan view of a schematic configuration of an organic EL display device according to a first embodiment of the present invention.

FIG. 2 is a plan view of the organic EL display device according to the first embodiment of the present invention. The plan view schematically shows an arrangement of, for example, a first frame wire, a second frame wire, a trench, a first dam wall, and a second dam wall.

FIG. 3 is a plan view of a display region in the organic EL display device according to the first embodiment of the present invention.

FIG. 4 is a cross-sectional view of the display region in the organic EL display device, taken from line IV-IV in FIG. 1.

FIG. 5 is an equivalent circuit diagram illustrating a TFT layer included in the organic EL display device according to the first embodiment of the present invention.

FIG. 6 is a cross-sectional view of an organic EL layer included in the organic EL display device according to the first embodiment of the present invention.

FIG. 7 is a cross-sectional view of a frame region in the organic EL display device, taken from line VII-VII in FIG. 2.

FIG. 8 is a cross-sectional view of the frame region in the organic EL display device, taken from line VIII-VIII in FIG. 2.

FIG. 9 is a cross-sectional view of the frame region in the organic EL display device, taken from line IX-IX in FIG. 2.

FIG. 10 is a plan view of a modification of the organic EL display device according to the first embodiment of the present invention. The plan view schematically shows an arrangement of, for example, the first frame wire, the second frame wire, the trench, the first dam wall, and the second dam wall. FIG. 10 corresponds to FIG. 2.

FIG. 11 is a cross-sectional view of a display region in an organic EL display device according to the second embodiment of the present invention. FIG. 11 corresponds to FIG. 4.

FIG. 12 is a cross-sectional view of a frame region in the organic EL display device according to the second embodiment of the present invention. FIG. 12 corresponds to FIG. 7.

FIG. 13 is a cross-sectional view of the frame region in the organic EL display device according to the second embodiment of the present invention. FIG. 13 corresponds to FIG. 8.

FIG. 14 is a cross-sectional view of a display region in an organic EL display device according to a third embodiment of the present invention. FIG. 14 corresponds to FIG. 4.

FIG. 15 is a cross-sectional view of a frame region in the organic EL display device according to the third embodiment of the present invention. FIG. 15 corresponds to FIG. 7.

FIG. 16 is a cross-sectional view of the frame region in the organic EL display device according to the third embodiment of the present invention. FIG. 16 corresponds to FIG. 8.

FIG. 17 is a cross-sectional view of the frame region in the organic EL display device according to the third embodiment of the present invention. FIG. 17 corresponds to FIG. 9.

FIG. 18 is a cross-sectional view of a display region in an organic EL display device according to a fourth embodiment of the present invention. FIG. 18 corresponds to FIG. 4.

FIG. 19 is a cross-sectional view of a frame region in the organic EL display device according to the fourth embodiment of the present invention. FIG. 19 corresponds to FIG. 7.

FIG. 20 is a cross-sectional view of a frame region in the organic EL display device according to the fourth embodiment of the present invention. FIG. 20 corresponds to FIG. 8.

FIG. 21 is a plan view of an organic EL display device according to a fifth embodiment of the present invention. The plan view schematically shows an arrangement of, for example, the first frame wire, the second frame wire, the trench, the first dam wall, and the second dam wall. FIG. 21 corresponds to FIG. 2.

FIG. 22 is a cross-sectional view of a frame region in the organic EL display device, taken from line XXII-XXII in FIG. 21.

### DESCRIPTION OF EMBODIMENTS

Described below in derail are embodiments of the present invention, with reference to the drawings. Note that the present invention shall not be limited to the embodiments below.

### First Embodiment

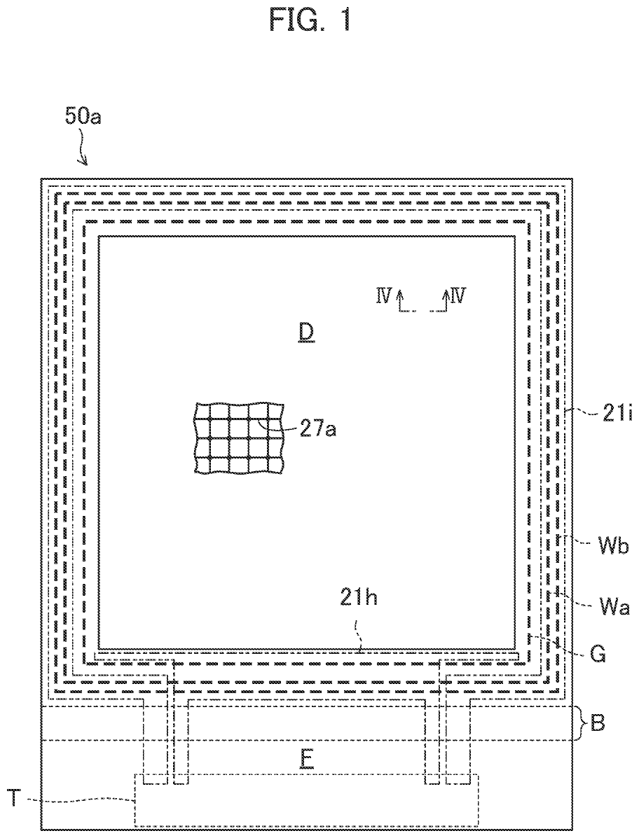

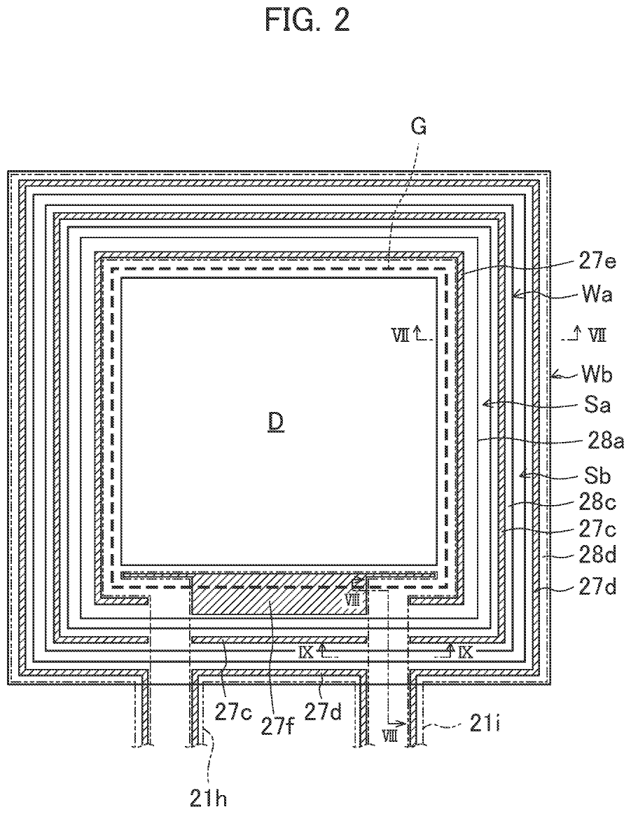

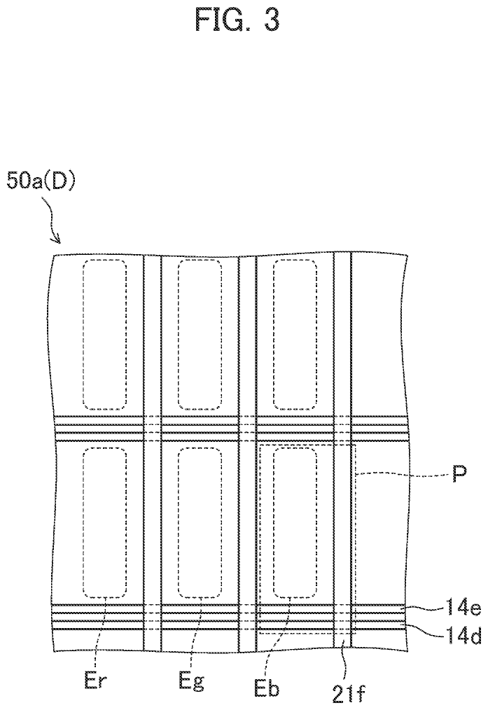

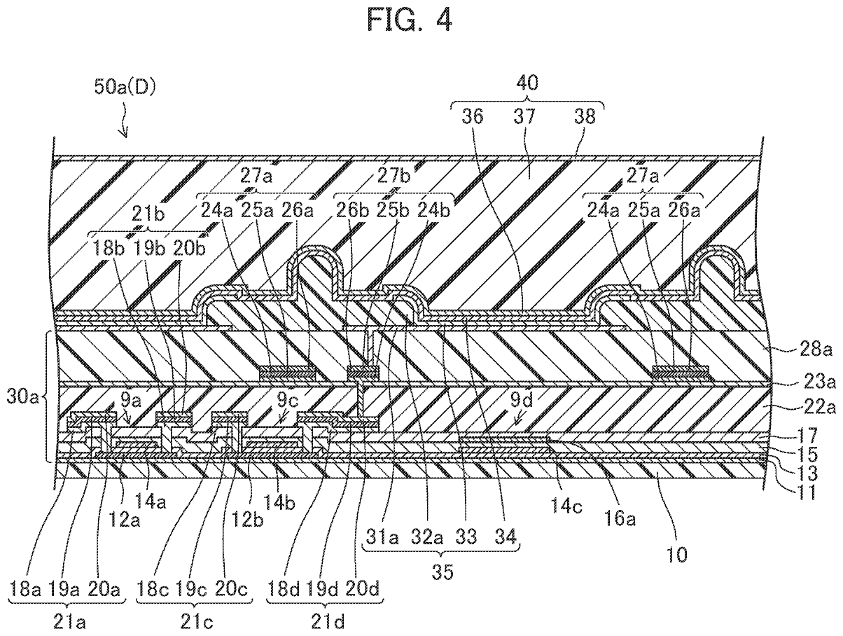

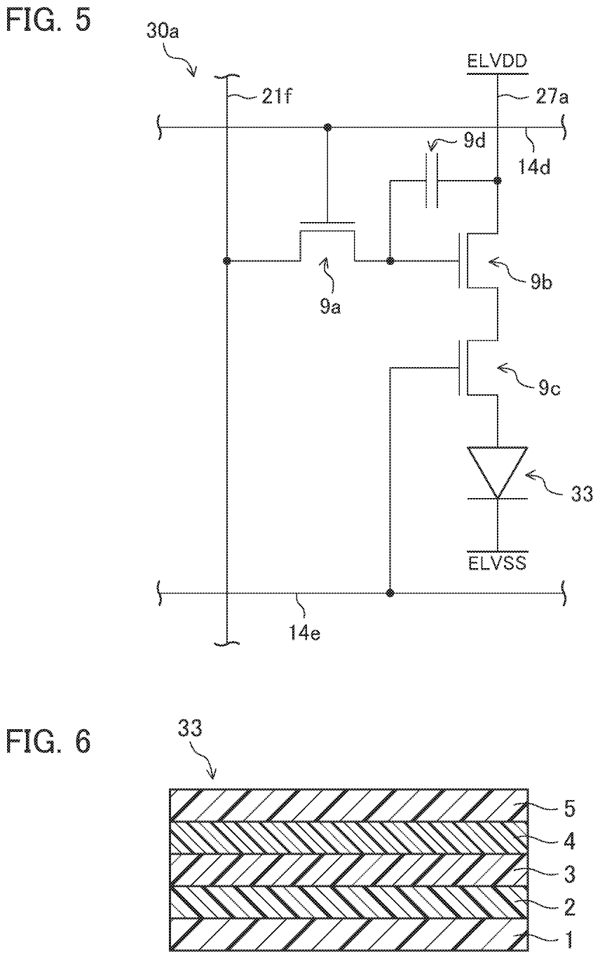

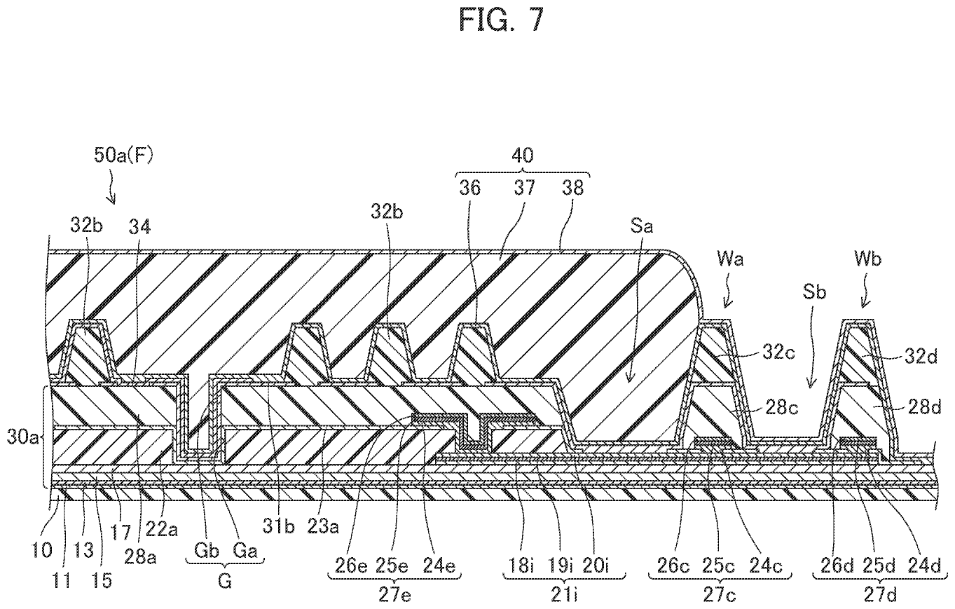

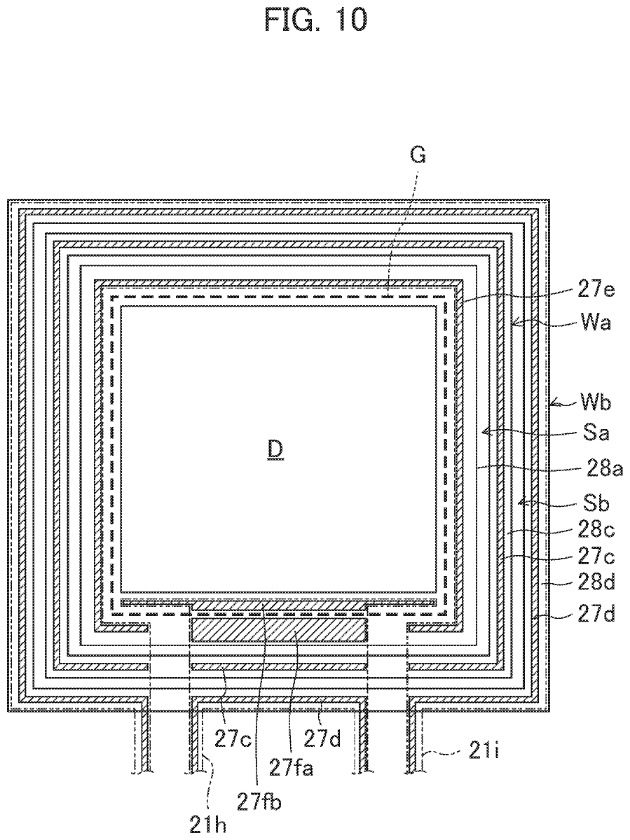

FIGS. 1 to 10 illustrate a first embodiment of a display device according to the present invention. Note that each of the embodiments below exemplifies an organic EL display device including an organic-EL-element layer, as a display device including a light-emitting-element layer. Here, FIG. 1 is a plan view of a schematic configuration of an organic EL display device 50a according to this embodiment. FIG. 2 is a plan view of the organic EL display device 50a. The plan view schematically shows an arrangement of, for example, a first frame wire 21h, a second frame wire 21i, a trench G, a first dam wall Wa, and a second dam wall Wb. FIG. 3 is a plan view of a display region D in the organic EL display device 50a. FIG. 4 is a cross-sectional view of the display region D in the organic EL display device 50a, taken from line IV-IV in FIG. 1. FIG. 5 is an equivalent circuit diagram illustrating a TFT layer 30a included in the organic EL display device 50a. FIG. 6 is a cross-sectional view of an organic EL layer 33 included in the organic EL display device 50a. FIGS. 7, 8, and 9 are cross-sectional views of a frame region F in the organic EL display device 50a, taken from lines VII-VII, VIII-VIII, and IX-IX in FIG. 2. FIG. 10 is a plan view of a modification of the organic EL display device 50a. The plan view schematically shows an arrangement of, for example, the first frame wire 21h, the second frame wire 21i, the trench G, the first dam wall Wa, and the second dam wall Wb. FIG. 10 corresponds to FIG. 2.

As illustrated in FIG. 1, the organic EL display device 50a includes, for example: the display region D shaped into a rectangle and displaying an image; and the frame region F shaped into a rectangle frame and provided around the display region D. Note that, in this embodiment, the display region D is, for example, rectangular. Examples of the rectangle include such substantial rectangles as a rectangle having arc-like sides, a rectangle having rounded corners, and a rectangle having partially notched sides.

As illustrated in FIG. 3, the display region D includes a plurality of sub-pixels P arranged in a matrix. Moreover, in the display region D, as illustrated in FIG. 3, for example, sub-pixels P having red light-emitting areas Er for presenting red, sub-pixels P having green light-emitting areas Eg for presenting green, and sub-pixels P having blue light-emitting areas Eb for presenting blue are provided next to each other. Note that, in the display region D, for example, neighboring three of the sub-pixels P each having one of a red light-emitting area Er, a green light-emitting area Eg, and a blue light-emitting area Eb constitute one pixel.

In FIG. 1, on a lower end portion of the frame region F, a terminal unit T is provided to extend in a single direction (in the horizontal direction in the drawing). Moreover, as illustrated in FIG. 1, the frame region F includes a folding portion B between the display region D and the terminal unit T. The folding portion B, extending in a single direction (in the horizontal direction in the drawing), is foldable around a folding axis in the horizontal direction at an angle of, for example, 180° (foldable in a U-shape). Furthermore, the terminal unit T includes a plurality of terminals arranged in a direction in which the terminal unit T extends. In addition, in the frame region F, a first planarization film 22a and a second planarization film 28a to be described later include the trench G shaped into a rectangular frame in plan view, and penetrating the first planarization film 22a and the second planarization film 28a as illustrated in FIGS. 2, 7, and 8. Note that, specifically, as illustrated in FIG. 7, the trench G includes: a first trench Ga formed in the first planarization film 22a; and a second trench Gb formed in the second planarization film 28a.

As illustrated in FIG. 4, the organic EL display device 50a includes: a resin substrate layer 10 provided as a base substrate; the TFT layer 30a provided on the resin substrate layer 10; an organic-EL-element layer 35 provided on the TFT layer 30a and serving as a light-emitting-element layer; and a sealing film 40 provided to cover the organic-EL-element layer 35.

The resin substrate layer 10 is made of, for example, polyimide resin.

As illustrated in FIG. 4, the TFT layer 30a includes: a base coat film 11 provided on the resin substrate layer 10; and a plurality of first TFTs 9a, a plurality of second TFT 9b (see FIG. 5), a plurality of third TFTs 9c, and a plurality of capacitors 9d all of which are provided on the base coat film 11. Moreover, the TFT layer 30a in FIG. 4 includes: the first planarization film 22a; a protective film 23a; and the second planarization film 28a, all of which are provided in the stated order above the first TFTs 9a, the second TFTs 9b, the third TFTs 9c, and the capacitors 9d.

The TFT layer 30a in FIG. 4 includes: semiconductor layers 12a and 12b; a gate insulating film 13; gate electrodes 14a and 14b and a lower wiring layer 14c (a first electrode layer); a first interlayer insulating film 15; an upper wiring layer 16a (a second electrode layer); a second interlayer insulating film 17; source electrodes 21a and 21c and drain electrodes 21b and 21d (a first wiring layer); the first planarization film 22a; the protective film 23a; a power supply line 27a and a relay electrode 27b (a second wiring layer); and the second planarization film 28a, all of which are stacked on top of another in the stated order above the base coat film 11.

As illustrated in FIGS. 3 and 5, the TFT layer 30a includes a plurality of gate lines 14d in the display region D horizontally extending in parallel with one another in the drawings. Moreover, as illustrated in FIGS. 3 and 5, the TFT layer 30a includes a plurality of light-emission control lines 14e in the display region D horizontally extending in parallel with one another in the drawings. Note that the gate lines 14d and the light-emission control lines 14e are formed of the same material as, and in the same layer as, the gate electrodes 14a and 14b and the lower wiring layer 14c are. The gate lines 14d and the light-emission control lines 14e are provided to serve as the first electrode layer together with the gate electrodes 14a and 14b and the lower wiring layer 14c. Moreover, as illustrated in FIG. 3, the light-emission control lines 14e and the gate lines 14d are provided next to each other. Furthermore, as illustrated in FIGS. 3 and 5, the TFT layer 30a includes a plurality of source lines 21f in display region D vertically extending in parallel with one another in the drawings. Note that the source lines 21f are formed of the same material as, and in the same layer as, the source electrodes 21a and 21c and the drain electrodes 21b and 21d are. The source lines 21f are provided to serve as the first wiring layer together with the source electrodes 21a and 21c, and the drain electrodes 21b and 21d. In addition, as illustrated in FIG. 1, the TFT layer 30a includes the power supply line 27a in display region D provided in a grid form and serving as the second wiring layer. Note that, as illustrated in FIG. 4, the power supply line 27a includes: a lower metal film 24a; an intermediate metal film 25a; and an upper metal film 26a, all of which are stacked on top of another in the stated order above the protective film 23a. Moreover, in the TFT layer 30a, as illustrated in FIG. 5, each of the sub-pixels P includes a first TFT 9a, a second TFT 9b, a third TFT 9c, and a capacitor 9d.

The base coat film 11 is, for example, a monolayer inorganic insulating film made of such a material as silicon nitride, silicon oxide, or silicon oxide nitride. Alternatively, the base coat film 11 is a multilayer inorganic insulating film made of these materials.

As illustrated in FIG. 5, in each sub-pixel P, the first TFT 9a is electrically connected to the corresponding gate line 14d, source line 21f, and second TFT 9b. Moreover, the first TFT 9a illustrated in FIG. 4 includes: the semiconductor layer 12a; the gate insulating film 13; the gate electrode 14a; the first interlayer insulating film 15; the second interlayer insulating film 17; and the source electrode 21a and the drain electrode 21b, all of which are provided in the stated order above the base coat film 11. Here, the semiconductor layer 12a illustrated in FIG. 4 is, for example, shaped into an island and provided above the base coat film 11. As will be described later, the semiconductor layer 12a has a channel region, a source region, and a drain region. Moreover, the semiconductor layer 12a, and the semiconductor layer 12b to be described later, are formed of, for example, such a film as a low-temperature polysilicon film or an In—Ga—Zn—O-based oxide semiconductor film. Furthermore, the gate insulating film 13 illustrated in FIG. 4 is provided to cover the semiconductor layer 12a. In addition, the gate electrode 14a illustrated in FIG. 4 is provided on the gate insulating film 13 to overlap the channel region of the semiconductor layer 12a. Moreover, the first interlayer insulating film 15 and the second interlayer insulating film 17 illustrated in FIG. 4 are provided in the stated order to cover the gate electrode 14a. Furthermore, the source electrode 21a and the drain electrode 21b illustrated in FIG. 4 are spaced apart from each other on the second interlayer insulating film 17. In addition, as illustrated in FIG. 4, the source electrode 21a and the drain electrode 21b are respectively and electrically connected to the source region and the drain region of the semiconductor layer 12a through contact holes each formed in a multilayer film including the gate insulating film 13, the first interlayer insulating film 15, and the second interlayer insulating film 17. Moreover, as illustrated in FIG. 4, the source electrode 21a includes: a lower metal film 18a; an intermediate metal film 19a; and an upper metal film 20a, all of which are stacked on top of another above the second interlayer insulating film 17. Furthermore, as illustrated in FIG. 4, the drain electrode 21b includes: a lower metal film 18b; an intermediate metal film 19b; and an upper metal film 20b, all of which are stacked on top of another above the second interlayer insulating film 17. Note that each of the lower metal films 18a and 18b, the upper metal films 20a and 20b, and lower metal films 18c and 18d and upper metal films 20c and 20d to be described later, is, for example, such a titanium-based metal film as a titanium film or a titanium alloy film. Moreover, each of the interlayer metal films 19a and 19b, and interlayer metal films 19c and 19d, is, for example, such an aluminum-based metal film as an aluminum film or an aluminum alloy film. Furthermore, each of the gate insulating film 13, the first interlayer insulating film 15, the second interlayer insulating film 17, and the protective film 23a is a monolayer inorganic insulating film made of such a material as, for example, silicon nitride, silicon oxide, or silicon oxide nitride. Alternatively, each of the films is a multilayer film made of these materials.

As illustrated in FIG. 5, in each sub-pixel P, the second TFT 9b is electrically connected to the corresponding first TFT 9a, power supply line 27a, and third TFT 9c. Note that the second TFT 9b is substantially the same in structure as the first TFT 9c and the third TFT 9c to be described later.

As illustrated in FIG. 5, in each sub-pixel P, the third TFT 9c is electrically connected to the corresponding second TFT 9b, power supply line 27a, and light-emission control line 14e. Moreover, the third TFT 9c illustrated in FIG. 4 includes: the semiconductor layer 12b; the gate insulating film 13; the gate electrode 14b; the first interlayer insulating film 15; the second interlayer insulating film 17; and the source electrode 21c and the drain electrode 21d, all of which are provided above the base coat film 11 in the stated order. Here, the semiconductor layer 12b illustrated in FIG. 4 is, for example, shaped into an island and provided above the base coat film 11. Similar to the semiconductor layer 12a, the semiconductor layer 12b has a channel region, a source region, and a drain region. Moreover, the gate insulating film 13 illustrated in FIG. 4 is provided to cover the semiconductor layer 12b. Furthermore, the gate electrode 14b illustrated in FIG. 4 is provided on the gate insulating film 13 to overlap the channel region of the semiconductor layer 12b. In addition, the first interlayer insulating film 15 and the second interlayer insulating film 17 illustrated in FIG. 4 are provided in the stated order to cover the gate electrode 14b. Moreover, the source electrode 21c and the drain electrode 21d illustrated in FIG. 4 are spaced apart from each other on the second interlayer insulating film 17. Furthermore, as illustrated in FIG. 4, the source electrode 21c and the drain electrode 21d are respectively and electrically connected to the source region and the drain region of the semiconductor layer 12b through contact holes each formed in a multilayer film including the gate insulating film 13, the first interlayer insulating film 15, and the second interlayer insulating film 17. In addition, as illustrated in FIG. 4, the source electrode 21c includes: the lower metal film 18c; the intermediate metal film 19c; and the upper metal film 20c, all of which are stacked on top of another above the second interlayer insulating film 17. Moreover, as illustrated in FIG. 4, the drain electrode 21d is electrically connected to the relay electrode 27b through a contact hole formed in the first planarization film 22a and the protective film 23a. Furthermore, as illustrated in FIG. 4, the drain electrode 21d includes: the lower metal film 18d, the intermediate metal film 19d; and the upper metal film 20d, all of which are stacked on top of another above the second interlayer insulating film 17. In addition, the relay electrode 27b is provided as the second wiring layer. As illustrated in FIG. 4, the relay electrode 27b includes: a lower metal film 24b; an intermediate metal film 25b; and an upper metal film 26b, all of which are stacked on top of another above the protective film 23a. Note that each of the lower metal film 24b and the upper metal film 26b, and the lower metal film 24a and the upper metal film 26a described above, is, for example, such a titanium-based metal film as a titanium film or a titanium alloy film. Moreover, each of the interlayer metal film 25b, and the interlayer metal film 25a described above, is, for example, such an aluminum-based metal film as an aluminum film or an aluminum alloy film.

Note that, in this embodiment, the first TFTs 9a, the second TFTs 9b, and the third TFTs 9c are top gate TFTs. Alternatively, the first TFTs 9a, the second TFTs 9b, and the third TFTs 9c may be bottom gate TFTs.

As illustrated in FIG. 5, in each sub-pixel P, the capacitor 9d is electrically connected to the corresponding first TFT 9a and power supply line 27a. Here, as illustrated in FIG. 4, the capacitor 9d includes: the lower wiring layer 14c provided to serve as the first electrode layer; the first interlayer insulating film 15 provided to cover the lower wiring layer 14c; and the upper wiring layer 16a provided on the first interlayer insulating film 15 and serving as the second electrode layer to overlap the lower insulating film 14c. Note that the upper wiring layer 16a is electrically connected to the power supply line 27a through a not-shown contact hole formed in the second interlayer insulating film 17, the first planarization film 22a, and the protective film 23a.

The first planarization film 22a and the second planarization film 28a, and an edge cover 32a to be described later, are made of, for example, such an organic resin material as polyimide resin, acrylic resin, or novolak resin.

The organic-EL-element layer 35 includes a plurality of organic EL elements arranged in a matrix. As illustrated in FIG. 4, the organic-EL-element layer 35 includes: a plurality of first electrodes 31a; the edge cover 32a; a plurality of the organic EL layers 33; and a second electrode 34, all of which are provided above the TFT layer 30a in the stated order.

The plurality of first electrodes 31a illustrated in FIG. 4 are provided on the planarization film 28a in a matrix, so that each of the first electrodes 21a corresponds to one of the sub-pixels P. Here, as illustrated in FIG. 4, each first electrode 31a is electrically connected to the drain electrode 21d of the corresponding third TFT 9c, through a contact hole formed in the first planarization film 22a and the protective film 23a and through a contact hole formed in the relay electrode 27b and the second planarization film 28a. Moreover, the first electrodes 31a are capable of injecting holes into the organic EL layers 33. Furthermore, preferably, the first electrodes 31a are formed of a material having a high work function in order to improve efficiency in injecting the holes into the organic EL layers 33. Exemplary materials of the first electrodes 31a include such metal materials as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Moreover, the exemplary materials of the first electrodes 31a may also include an alloy of astatine (At)/astatine dioxide (AtO₂). Furthermore, exemplary materials of the first electrodes 31a may include such conductive oxides as tin oxide (SnO), zinc oxide (ZnO), indium tin oxide (ITO), and indium zinc oxide (IZO). In addition, each of the first electrodes 31a may be a multilayer including two or more layers made of the above materials. Note that exemplary compound materials having a large work function include indium tin oxide (ITO) and indium zinc oxide (IZO).

As illustrated in FIG. 4, the edge cover 32a is provided in a grid form in common among the plurality of sub-pixels P, in order to cover a peripheral end portion of each first electrode 31a.

As illustrated in FIG. 4, the plurality of the organic EL layers 33 are provided in a matrix, so that each of the organic EL layers 33 is disposed on a corresponding one of the first electrodes 31a and provided to a corresponding one of the sub-pixels P. Here, as illustrated in FIG. 6, each of the organic EL layers 33 includes: a hole-injection layer 1; a hole-transport layer 2; a light-emitting layer 3; an electron-transport layer 4; and an electron-injection layer 5, all of which are provided on top of another above the first electrode 31a in the stated order.

The hole injection layer 1, also referred to as an anode buffer layer, is capable of approximating the energy levels of the first electrode 31a and the organic EL layer 33 and increasing efficiency in injection of the holes from the first electrode 31a to the organic EL layer 33. Here, exemplary materials of the hole injection layer 1 may include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole-transport layer 2 is capable of improving efficiency in transporting the holes from the first electrode 31a to the organic EL layer 33. Here, exemplary materials of the hole transport-layer 2 may include a porphyrin derivative, an aromatic tertiary amine compound, a styryl amine derivative, polyvinylcarbazole, poly-p-phenylene vinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, and zinc selenide.

The light-emitting layer 3 is a region into which the holes and the electrons are injected from the first electrode 31a and the second electrode 24 and recombine with each other, when a voltage is applied by the first electrode 31a and the second electrode 34. Here, the light-emitting layer 3 is formed of a material with high light emission efficiency. Exemplary materials of the light-emitting layer 3 may include a metal oxinoid compound [an 8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rodamine derivative, an acridine derivative, phenoxazone, a quinacridone derivative, rubrene, poly-p-phenylene vinylene, and polysilane.

The electron-transport layer 4 is capable of efficiently transporting the electrons to the light-emitting layer 3. Here, exemplary materials of the electron-transport layer 4 may include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron-injection layer 5 is capable of approximating the energy levels of the second electrode 34 and the organic EL layer 33, and increasing efficiency in injection of the electrons from the second electrode 34 to the organic EL layer 33. Such a feature makes it possible to decrease a drive voltage of each of the organic EL elements included in the organic-EL-element layer 35. Note that the electron-injection layer 5 may also be referred to as a cathode buffer layer. Here, exemplary materials of the electron-injection layer 5 may include: such inorganic alkaline compounds as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 4, the second electrode 34 is provided in common among the plurality of sub-pixels P, in order to cover each of the organic EL layers 33 and the edge cover 32a. Moreover, the second electrode 34 is capable of injecting electrons into the organic EL layer 33. Furthermore, the second electrode 34 is preferably made of a material having a low work function in order to improve efficiency in injection of the electrons into the organic EL layers 33. Here, exemplary materials of the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Moreover, the second electrode 34 may also be formed of an alloy of, for example, magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), or lithium fluoride (LiF)/calcium (Ca)/aluminum (Al). Furthermore, the second electrode 34 may also be formed of such conductive oxides as tin oxide (SnO), zinc oxide (ZnO), indium tin oxide (ITO), and indium zinc oxide (IZO). In addition, the second electrode 34 may be a multilayer including two or more layers made of the above materials. Note that exemplary materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and fluoride (LiF)/calcium (Ca)/aluminum (Al).

As illustrated in FIG. 4, the sealing film 40 is provided to cover the second electrode 34. The sealing film 40 includes: a first inorganic sealing film 36; an organic sealing film 37; and a second sealing film 38, all of which are stacked on top of another in the stated order above the second electrode 34. The sealing film 40 is capable of protecting each of the organic EL layers 33 included in the organic-EL-element layer 35 from water and oxygen. Here, each of the first inorganic sealing film 36 and the second inorganic sealing film 38 is formed of, for example, such an inorganic insulating film as a silicon nitride film, a silicon oxide film, or a silicon oxide nitride film. Moreover, exemplary materials of the organic sealing film 37 include such organic materials as acrylic resin, epoxy resin, silicon resin, polyuria resin, parylene resin, polyimide resin, and polyamide resin.

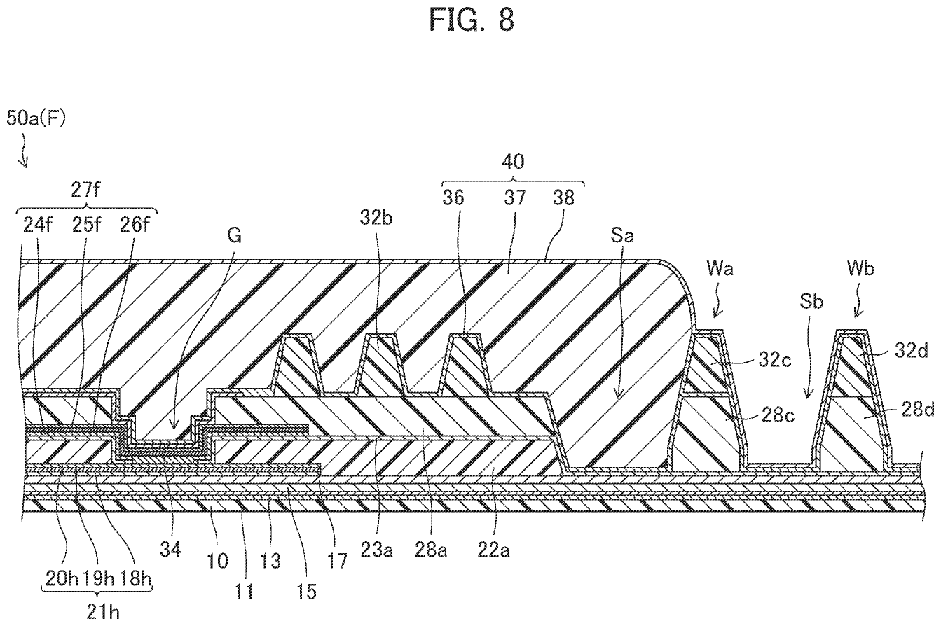

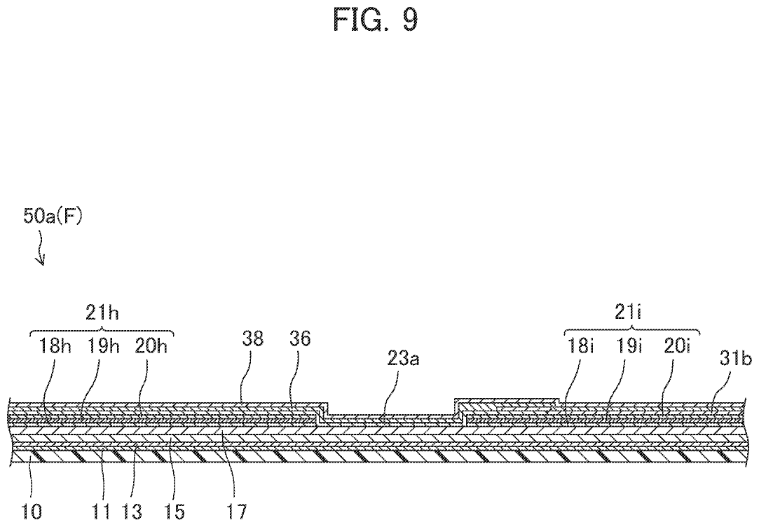

Furthermore, as illustrated in FIGS. 1 and 2, the organic EL display device 50a includes the first frame wire 21h in the frame region F. The first frame wire 21h has a relatively wide strip portion extending along a center portion of a lower side of the display region D in the drawings. The first frame wire 21h has relatively narrow strip portions each extending along one of opposing end portions of the lower side of the display region D in the drawings. The first frame wire 21h has wide opposing end portions provided across from the display region D and extending to the terminal unit T. Here, the first frame wire 21h is electrically connected to the power supply line 27a in the frame region F toward the display region D. At the terminal unit T, the first frame wire 21h receives a high power-supply voltage (ELVDD). Note that the first frame wire 21h is provided to serve as the first wiring layer. As illustrated in FIGS. 8 and 9, the first frame wire 21h includes: a lower metal film 18h; an intermediate metal film 19h; and an upper metal film 20h, all of which are stacked on top of another in the stated order above the second interlayer insulating film 17. The first frame wire 21h is formed of the same material as, and in the same layer as, the source electrodes 21a and 21c and the drain electrodes 21b and 21d are.

Moreover, as illustrated in FIGS. 1 and 2, the organic EL display device 50a includes the second frame wire 21i in the frame region F. The second frame wire 21i is shaped into a substantial C-shape and provided outside the trench G. The second frame wire 21i has opposing end portions extending to the terminal unit T. Here, as illustrated in FIG. 7, the second frame wire 21i is electrically connected to the second electrode 34 through a conductive layer 31b formed in the trench G. At the terminal unit T, the second frame wire 21i receives a low power-supply voltage (ELVSS). Note that the second frame wire 21i is provided to serve as the first wiring layer. As illustrated in FIGS. 7 and 9, the second frame wire 21i includes: a lower metal film 18i; an intermediate metal film 19i; and an upper metal film 20i, all of which are stacked on top of another in the stated order above the second interlayer insulating film 17. The second frame wire 21i is formed of the same material as, and in the same layer as, the source electrodes 21a and 21c and the drain electrodes 21b and 21d are. Moreover, as illustrated in FIG. 7, the conductive layer 31b is formed of the same material as, and in the same layer as, the first electrodes 31a are. The conductive layer 31b is in contact with the second electrode 34 and provided also inside the trench G. The conductive layer 31b electrically connects the second frame wire 21i and the second electrode 34 together.

Furthermore, as illustrated in FIGS. 1 and 2, the organic EL display device 50a includes a first dam wall Wa and a second dam wall Wb in the frame region F. The first dam wall Wa is shaped into a frame and provided outside the trench G to surround the display region D. The second dam wall Wb is shaped into a frame and provided around the first dam wall Wa.

As illustrated in FIG. 7, the first dam wall Wa includes: a first metal protruding portion 27c provided to serve as the second wiring layer; an inner lower resin layer 28c formed of the same material as, and in the same layer as, the second planarization film 28a is, and provided on the first metal protruding portion 27c to serve as a first resin protruding portion; and an inner upper resin layer 32c formed of the same material as, and in the same layer as, the edge cover 32a, and provided above the inner lower resin layer 28c through the conductive layer 31b in order to serve as a third resin protruding portion. Here, the first dam wall Wa is provided to overlap with a peripheral end portion of the organic sealing film 37 in the sealing film 40, in order to reduce spread of ink that forms the organic sealing film 37 of the sealing film 40. Moreover, as illustrated in FIGS. 2, 7, and 8, the first planarization film 22a and the second planarization film 28a include a first slit Sa shaped into a frame, provided between the display region D and the first dam wall Wa, and penetrating the first planarization film 22a and the second planarization film 28a. Note that, in the first slit Sa, the first frame wire 21h and the second frame wire 21i have respective edge portions facing each other and covered with the protective film 23a (see FIG. 9). Moreover, the first metal protruding portion 27c is provided to electrically connect to either the first frame wire 21h or the second frame wire 21i. Note that, as illustrated in FIG. 2, the first metal protruding portion 27c electrically connected to the first frame wire 21h is provided along a portion (an intermediate portion) of one side (the lower side in the drawing), of the display region D, along the terminal unit T. Moreover, as illustrated in FIG. 2, the first metal protruding portion 27c electrically connected to the second frame wire 21i is provided along: another portion (opposing end portions) of the one side (the lower side in the drawing), of the display region D, along the terminal unit T; and three sides (a left side, a right side, and an upper side in the drawing), of the display region D, not along the terminal unit T. Furthermore, as illustrated in FIG. 7, the first metal protruding portion 27c includes: a lower metal film 24c; an intermediate metal film 25c; and an upper metal film 26c, all of which are stacked on top of another above the protective film 23a.

As illustrated in FIG. 7, the second dam wall Wb includes: a second metal protruding portion 27d provided to serve as the second wiring layer; an outer lower resin layer 28d formed of the same material as, and in the same layer as, the second planarization film 28a is, and provided on the second metal protruding portion 27d to serve as a second resin protruding portion; and an outer upper resin layer 32d formed of the same material as, and in the same layer as, the edge cover 32a, and provided above the outer lower resin layer 28d through the conductive layer 31b in order to serve as a fourth resin protruding portion. Here, as illustrated in FIGS. 2, 7, and 8, the second planarization film 28a includes a second slit Sb shaped into a frame, provided between the first dam wall Wa and the second dam wall Wb, and penetrating the second planarization film 28a. Note that, in the second slit Sb, the first frame wire 21h and the second frame wire 21i have respective edge portions facing each other and covered with the protective film 23a (see FIG. 9). Moreover, the second metal protruding portion 27d is provided to electrically connect to either the first frame wire 21h or the second frame wire 21i. Note that, as illustrated in FIG. 2, the second metal protruding portion 27d electrically connected to the first frame wire 21h is provided along a portion (an intermediate portion) of one side (the lower side in the drawing), of the display region D, along the terminal unit T. Moreover, as illustrated in FIG. 2, the second metal protruding portion 27d electrically connected to the second frame wire 21i is provided along: another portion (opposing end portions) of the one side (the lower side in the drawing), of the display region D, along the terminal unit T; and three sides (a left side, a right side, and an upper side in the drawing), of the display region D, not along the terminal unit T. Furthermore, as illustrated in FIG. 7, the second metal protruding portion 27d includes: a lower metal film 24d; an intermediate metal film 25d; and an upper metal film 26d, all of which are stacked on top of another above the protective film 23a.

In addition, as illustrated in FIG. 2, the organic EL display device 50a includes a first metal layer 27e in the frame region F. The first metal layer 27e is shaped into a substantial C-shape, and provided between the trench G and the first slit Sa to serve as the second wiring layer. Here, as illustrated in FIG. 7, the first metal layer 27e includes: a lower metal film 24e; an intermediate metal film 25e; and an upper metal film 26e, all of which are stacked on top of another in the stated order above the protective film 23a. The first metal layer 27e is provided to be electrically connected to the second frame wire 21i through a contact hole formed in the first planarization film 22a and the protective film 23a.

Moreover, as illustrated in FIG. 2, the organic EL display device 50a includes a terminal metal layer 27f in the frame region F. The terminal metal layer 27f is shaped into a substantial T-shape, and provided to overlap with a lower side portion of the trench G in the drawing. Here, as illustrated in FIG. 8, the terminal metal layer 27f includes: a lower metal film 24f; an intermediate metal film 25f; and an upper metal film 26f, all of which are stacked on top of another in the stated order above the protective film 23a. The terminal metal layer 27f is provided to be electrically connected to the first frame wire 21h through a contact hole formed in the protective film 23a inside the trench G. Note that this embodiment exemplifies the terminal metal layer 27f shaped into a substantial T-shape and provided in a single piece. Alternatively, as illustrated in FIG. 10, this embodiment may include terminal metal layers 27fa and 27fb separately provided across the trench G.

Furthermore, as illustrated in FIGS. 7 and 8, the organic EL display device 50a includes a plurality of peripheral photo spacers 32b in the frame region F. The plurality of peripheral photo spacers 32b are shaped into islands, and protruding upwards at opposing edge portions of the trench G. Here, the peripheral photo spacers 32b are formed of the same material as, and in the same layer as, the edge cover 32a is. In addition, a portion protruding upwards on the surface of the edge cover 32a is a pixel photo spacer shaped into an island. Note that, in FIG. 7, the conductive layer 31b is intermittently illustrated. However, the conductive layer 31b is formed in a single piece, and merely has openings overlapping with the peripheral photo spacers 32b.

The above organic EL display device 50a displays an image as follows: In each sub-pixel P, a gate signal is input through the gate line 14d to the first TFT 9a. The first TFT 9a turns ON. Through the source line 21f, a predetermined voltage corresponding a source signal is written in the gate electrode 14b of the second TFT 9b and the capacitor 9d. Through the light-emission control line 14e, a light-emission control signal is input into the third TFT 9c. Then, the third TFT 9c turns ON. In accordance with a gate voltage of the second TFT 9b, a current is supplied from the power supply line 27a to the organic EL layer 33. The supplied current allows the light-emitting layer 3 of the organic EL layer 33 to emit light and display the image. Note that, in the organic EL display device 50a, even if the first TFT 9a turns OFF, the gate voltage of the second TFT 9b is held in the capacitor 9d. Hence, the light-emitting layer 3 keeps emitting light until a gate signal of the next frame is input.

Described next is a method for producing the organic EL display device 50 of this embodiment. Note that the method for producing the organic EL display device 50a of this embodiment includes: a TFT layer forming step; an organic-EL-element layer forming step; and a sealing film forming step.

TFT Layer Forming Step

First, for example, on the resin substrate layer 10 formed on a glass substrate, an inorganic insulating film (a thickness of approximately 1000 nm) such as a silicon oxide film is deposited by, for example, plasma chemical vapor deposition (CVD) to form the base coat film 11.

Then, throughout the substrate on which the base coat film 11 is formed, for example, an amorphous silicon film (a thickness of approximately 50 nm) is deposited by the plasma CVD. The amorphous silicon film is crystalized by a technique such as laser annealing to form a semiconductor film of a polysilicon film. After that, the semiconductor film is patterned to form a layer such as the semiconductor layer 12a.

After that, throughout the substrate on which a layer such as the semiconductor layer 12a is formed, an inorganic insulating film (approximately 100 nm) such as an silicon oxide film is deposited by, for example, the plasma CVD to form the gate insulating film 13 to cover a layer such as the semiconductor layer 12a.

Moreover, throughout the substrate on which the gate insulating film 13 is formed, films such as an aluminum film (a thickness of approximately 350 nm) and a molybdenum nitride film (a thickness of approximately 50 nm) are sequentially deposited by, for example, sputtering. After that, the metal multilayer film of these metals is patterned to form the first electrode layer including the gate lines 14d.

Then, using lines such as the gate lines 14d as a mask, a layer such as the semiconductor layer 12a is doped with impurity ions and provided with a channel region, a source region, and a drain region.

After that, throughout the substrate including a layer such as the semiconductor layer 12a provided with the channel region, the source region, and the drain region, an inorganic insulating film (a thickness of approximately 100 nm) such as an silicon oxide film is deposited by, for example, the plasma CVD to form the first interlayer insulating film 15.

Then, throughout the substrate on which the first interlayer insulating film 15 is formed, films such as an aluminum film (a thickness of approximately 350 nm) and a molybdenum nitride film (a thickness of approximately 50 nm) are sequentially deposited by, for example, sputtering. After that, the metal multilayer film of these metals is patterned to form the second electrode layer including the upper wiring layer 16a.

Moreover, throughout the substrate on which the second electrode layer is formed, an inorganic insulating film (a thickness of approximately 500 nm) such as a silicon oxide film is deposited by, for example, the plasma CVD to form the second interlayer insulating film 17.

After that, the gate insulating film 13, the first interlayer insulating film 15, and the second interlayer insulating film 17 are patterned, so that contact holes are formed in these films.

Then, throughout the substrate in which the contact holes are formed, films such as a titanium film (a thickness of approximately 30 nm), an aluminum film (a thickness of approximately 300 nm), and a titanium film (a thickness of approximately 50 nm) are sequentially deposited by, for example, sputtering. After that, the metal multilayer film of these metals is patterned to form the first wiring layer including the source lines 21f.

Furthermore, throughout the substrate on which the first wiring layer is formed, a polyimide-based photosensitive resin film (a thickness of approximately 2 μm) is applied by, for example, spin-coating or slit-coating. The applied film is prebaked, exposed to light, developed, and postbaked to form the first planarization film 22a made of an organic insulating film.

After that, throughout the substrate on which the first planarization film 22a is formed, an inorganic insulating film (a thickness of approximately 500 nm) such as a silicon oxide film is deposited by, for example, the plasma CVD. The inorganic insulating film is patterned to form the protective film 23a.

Then, throughout the substrate on which the protective film 23a is formed, films such as a titanium film (a thickness of approximately 30 nm), an aluminum film (a thickness of approximately 300 nm), and a titanium film (a thickness of approximately 50 nm) are sequentially deposited by, for example, sputtering. After that, the metal multilayer film of these metals is patterned to form the second wiring layer including the power supply line 27a.

Finally, throughout the substrate on which the second wiring layer is formed, a polyimide-based photosensitive resin film (a thickness of approximately 2 μm) is applied by, for example, spin-coating or slit-coating. The applied film is prebaked, exposed to light, developed, and postbaked to form the second planarization resin film 28a made of an organic insulating film.

Through the above steps, the TFT layer 30a can be formed.

Organic-EL-Element Layer Forming Step

On the second planarization film 28a of the TFT layer 30a formed at the TFT layer forming step, the first electrodes 31a, the edge cover 32a, the organic EL layers 33 (each including the hole-injection layer 1, the hole-transport layer 2, the organic light-emitting layer 3, the electron-transport layer 4, and the electron-injection layer 5), and the second electrode 34 are formed by a known technique to form the organic-EL-element layer 35.

Sealing Film Forming Step

First, on the surface of the substrate on which the organic-EL-element layer 35 is formed at the organic-EL-element-layer forming step, an inorganic insulating film such as, for example, a silicon nitride film, a silicon oxide film, or a silicon nitride oxide film is deposited by the plasma CVD to form the first inorganic sealing film 36, using a mask.

Next, on the surface of the substrate on which the first inorganic film 36 is formed, an organic resin material such as acrylic resin is applied by, for example, ink-jet printing to form the organic sealing film 37.

After that, on the substrate on which the organic film 37 is formed, an inorganic insulating film such as, for example, a silicon nitride film, a silicon oxide film, or a silicon nitride oxide film is deposited by the plasma CVD to form the second inorganic film 38, using a mask. Hence, the second inorganic sealing film 38 is formed. Thus, the sealing film 40 is formed.

Finally, on the surface of the substrate on which the sealing film 40 is formed, a not-shown protective sheet is attached. After that, a laser beam is emitted on the glass substrate of the resin substrate layer 10 to remove the glass substrate from the bottom surface of the resin substrate layer 10. Furthermore, on the bottom surface of the resin substrate layer 10 from which the glass substrate removed, a not-shown protective sheet is attached.

Through the above steps, the organic EL display device 50a of this embodiment can be produced.

As described above, as to the organic EL display device 50a of this embodiment, the TFT layer 30a includes: the first electrode layer including the gate lines 14d; the first interlayer insulating film 15; the second electrode layer including the upper wiring layer 16a; the second interlayer insulating film 17; the first wiring layer including the source lines 21f; the first planarization film 22a; the protective film 23a; the second wiring layer including the power supply line 27a; and the second planarization film 28a, all of which are stacked on top of another in the stated order. Here, in the frame region F around the display region D, the first frame wire 21h is provided to extend to the terminal unit T to serve as the first wiring layer. The first frame wire 21h is electrically connected to the power supply line 27a toward the display region D. Moreover, in the frame region F, the second frame wire 21i is provided to extend to the terminal unit T to serve as the first wiring layer. The first frame wire 21i is electrically connected, through the conductive layer 31b, to the second electrode 34 toward the display region D. Furthermore, the first planarization film 22a and the second planarization film 28a include the first slit Sa shaped into a frame, provided between the display region D and the first dam wall Wa, and penetrating the first planarization film 22a and the second planarization film 28a. The first dam wall Wa overlaps with the peripheral end portion of the organic sealing film 37. In addition, around the first dam wall Wa, the second dam wall Wb is provided in the shape of a frame. Moreover, the second planarization film 28a includes the second slit Sb shaped into a frame, provided between the first dam wall Wa and the second dam wall Wb, and penetrating the second planarization film 28a. Then, in the first slit Sa and the second slit Sb, the first frame wire 21h and the second frame wire 21i have respective edge portions facing each other and covered with the protective film 23a. Hence, even if the first slit Sa and the second slit Sb are formed, the first dam wall Wa and the second dam wall Wb keep the first frame wire 21h and the second frame wire 21i from damage caused by side-etching with a developer to be used for forming the first planarization film 22a and the second planarization film 28a, an etchant to be used for forming the first electrodes 31a, and a developer to be used for forming the edge cover 32a. Such a feature can reduce the damage to the first frame wire 21h and the second frame wire 21i during the production steps of these wires. Moreover, the damage to the first frame wire 21h and the second frame wire 21i is reduced during the production steps of these wires, thereby making it possible to ensure sealing capability of the sealing film 40 formed above the first frame wire 21h and the second frame wire 21i. Such features can reduce deterioration of the organic EL layers 33, thereby contributing to improvement in reliability of the organic EL display device 50a.

Moreover, as to the organic EL display device 50a of this embodiment, the first dam wall Wa includes the first metal protruding portion 27c, and the second dam wall Wb includes the second metal protruding portion 27d. Thanks to such a feature, the first dam wall Wa and the second dam wall Wb are formed tall, and can block ink that forms the organic sealing film 37.

Furthermore, as to the organic EL display device 50a of this embodiment, the trench G, which is shaped into a frame and penetrates the first planarization film 22a and the second planarization film 28a, is provided around the display region D. Such a feature can keep water from moving to the display region D through the inside of such resin layers as the first planarization film 22a and the second planarization film 28a. As a result, the organic EL layers 33 can be kept from deterioration.

In addition, as to the organic EL display device 50a of this embodiment, the first metal protruding portion 27c and the second metal protruding portion 27d are provided to electrically connect to either the first frame wire 21h or the second frame wire 21i. Such a feature can reduce wiring resistance of the first frame wire 21h and the second frame wire 21i.

Moreover, as to the organic EL display device 50a of this embodiment, the first metal layer 27e is provided to electrically connect to the second frame wire 21i. Such a feature can reduce wiring resistance of the second frame wire 21i.

Furthermore, as to the organic EL display device 50a of this embodiment, the terminal metal layer 27f is provided to electrically connect to the first frame wire 21h. Such a feature can reduce wiring resistance of the first frame wire 21h.

In addition, as to the organic EL display device 50a of this embodiment, the surface of the first planarization film 22a is covered with the protective film 23a. Such a feature can keep the surface layer of the first planarization film 22a from being etched when, for example, the second wiring layer including the power supply line 27a is patterned by dry etching. As a result, the interior of the chamber of a dry etching apparatus can be kept from contamination.

### Second Embodiment

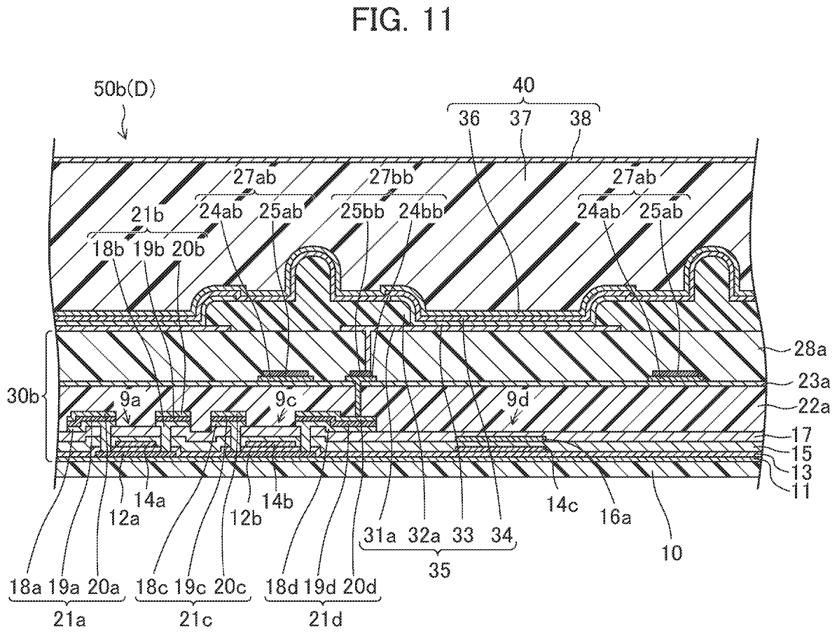

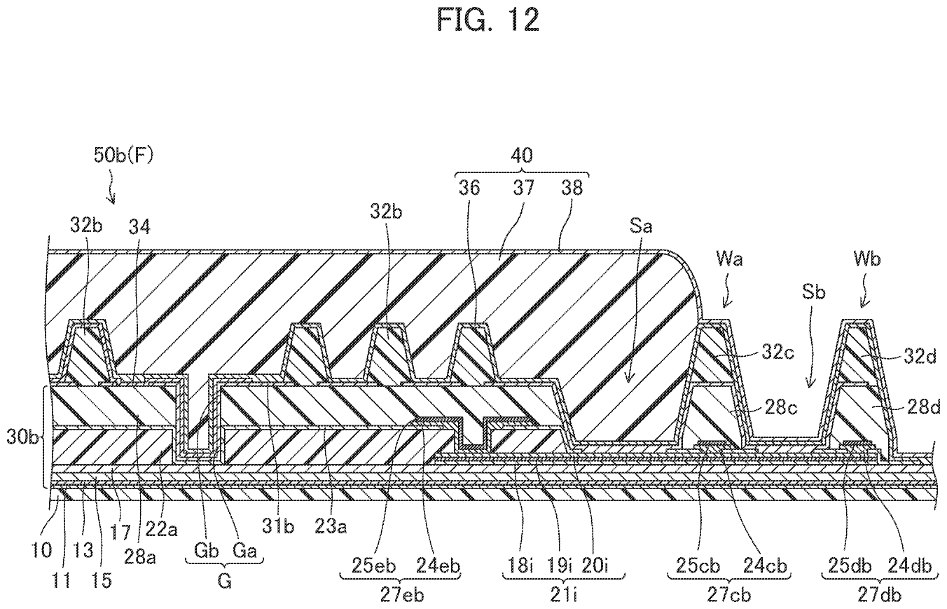

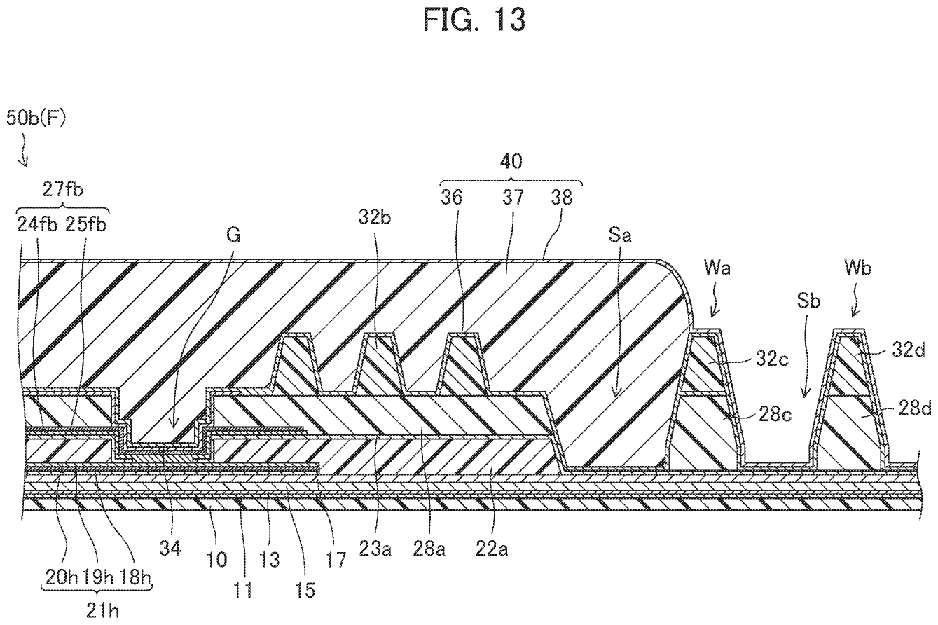

FIGS. 11 to 13 illustrate a second embodiment of a display device according to the present invention. Here, FIG. 11 is a cross-sectional view of the display region D in an organic EL display device 50b of this embodiment. FIG. 11 corresponds to FIG. 4. Moreover, FIGS. 12 and 13 are cross-sectional views of the frame region F in the organic EL display device 50b. FIG. 12 and FIG. 13 respectively correspond to FIG. 7 and FIG. 8. Note that, in the embodiments below, like reference signs designate identical or corresponding components in FIGS. 1 to 10. These components will not be elaborated upon.

The above first embodiment exemplifies the organic EL display device 50a including the second wiring layer made of a metal multilayer film having three layers. Whereas, this embodiment exemplifies the organic EL display device 50b including a second wiring layer made of a metal multilayer film having two layers.

Similar to the organic EL display device 50a of the above first embodiment, the organic EL display device 50b includes: the display region D; and the frame region F provided around the display region D. Moreover, as illustrated in FIG. 11, the organic EL display device 50b includes: the resin substrate layer 10; a TFT layer 30b provided on the resin substrate layer 10; the organic-EL-element layer 35 provided on the TFT layer 30b; and the sealing film 40 provided to cover the organic-EL-element layer 35.

Similar to the TFT layer 30a of the above first embodiment, the TFT layer 30b illustrated in FIG. 11 includes: the base coat film 11 provided on the resin substrate layer 10; and the plurality of first TFTs 9a, the plurality of second TFT 9b, the plurality of third TFTs 9c, and the plurality of capacitors 9d all of which are provided on the base coat film 11. Moreover, similar to the TFT layer 30a of the above first embodiment, the TFT layer 30b illustrated in FIG. 11 includes: the first planarization film 22a; the protective film 23a; and the second planarization film 28a, all of which are provided in the stated order above the first TFTs 9a, the second TFTs 9b, the third TFTs 9c, and the capacitors 9d.

The TFT layer 30b illustrated in FIG. 11 includes: the semiconductor layers 12a and 12b; the gate insulating film 13; the gate electrodes 14a and 14b and the lower wiring layer 14c (the first electrode layer); the first interlayer insulating film 15; the upper wiring layer 16a (the second electrode layer); the second interlayer insulating film 17; the source electrodes 21a and 21c and the drain electrodes 21b and 21d (the first wiring layer); the first planarization film 22a; the protective film 23a; a power supply line 27ab and a relay electrode 27bb (the second wiring layer); and the second planarization film 28a, all of which are stacked on top of another in the stated order above the base coat film 11.

Similar to the TFT layer 30a of the above first embodiment, the TFT layer 30b includes the plurality of gate lines 14d in the display region D extending in parallel with one another. Moreover, similar to the TFT layer 30a of the above first embodiment, the TFT layer 30b includes the plurality of light-emission control lines 14e in the display region D extending in parallel with one another. Furthermore, similar to the TFT layer 30a of the above first embodiment, the TFT layer 30b includes the plurality of source lines 21f in the display region D extending in parallel with one another. In addition, the TFT layer 30b includes the power supply line 27ab in display region D provided in a grid form and serving as the second wiring layer. Note that, as illustrated in FIG. 11, the power supply line 27ab includes: a lower metal film 24ab; and an upper metal film 26ab, both of which are stacked on top of another in the stated order above the protective film 23a. Moreover, in the TFT layer 30b, similar to the TFT layer 30a of the above first embodiment, each of the sub-pixels P includes a first TFT 9a, a second TFT 9b, a third TFT 9c, and a capacitor 9d. Furthermore, in the TFT layer 30b, the second TFT 9b in each sub-pixel P is electrically connected to the corresponding first TFT 9a, power supply line 27ab, and third TFT 9c. In addition, in the TFT layer 30b, the third TFT 9c in each sub-pixel P is electrically connected to the corresponding second TFT 9a, power supply line 27ab, and light-emission control line 14e. Moreover, in the TFT layer 30b, the drain electrode 21d of the third TFT 9c illustrated in FIG. 11 is electrically connected to the relay electrode 27bb through a contact hole formed in the first planarization film 22a and the protective film 23a. Note that the relay electrode 27bb is provided to serve as the second wiring layer. As illustrated in FIG. 11, the relay electrode 27bb includes: a lower metal film 24bb; and an upper metal film 25bb, both of which are stacked on top of another in the stated order above the protective film 23a. Furthermore, in the TFT layer 30b, the capacitor 9d in each sub-pixel P is electrically connected to the corresponding first TFT 9a and power supply line 27ab.

In addition, similar to the organic EL display device 50a of the above first embodiment, the organic EL display device 50b also includes the first frame wire 21h and the second frame wire 21i in the frame region F.

Moreover, similar to the organic EL display device 50a of the above first embodiment, the organic EL display device 50b includes the first dam wall Wa and the second dam wall Wb in the frame region F.

As illustrated in FIG. 12, the first dam wall Wa includes: a first metal protruding portion 27cb provided to serve as the second wiring layer; the inner lower resin layer 28c formed of the same material as, and in the same layer as, the second planarization film 28a is, and provided on the first metal protruding portion 27cb to serve as the first resin protruding portion; and the inner upper resin layer 32c formed of the same material as, and in the same layer as, the edge cover 32a, and provided above the inner lower resin layer 28c through the conductive layer 31b in order to serve as the third resin protruding portion. Here, the first metal protruding portion 27cb is provided to electrically connect to either the first frame wire 21h or the second frame wire 21i. Moreover, the first metal protruding portion 27cb illustrated in FIG. 12 includes: a lower metal film 24cb made of such a film as a titanium film and provided toward the resin substrate layer 10; and an upper metal film 25cb made of such a film as an aluminum film and provided toward the organic-EL-element layer 35. Furthermore, as illustrated in FIG. 12, the first metal protruding portion 27cb has an end portion shaped into a forward tapered shape so that the lower metal film 24cb protrudes further than the upper metal film 25cb. Note that, similar to the first metal protruding portion 27c of the above first embodiment, the first metal protruding portion 27cb, which is electrically connected to the first frame wire 21h, is provided along a portion of one side, of the display region D, along the terminal unit T. Moreover, similar to the first metal protruding portion 27c of the above first embodiment, the first metal protruding portion 27cb, which is electrically connected to the second frame wire 21i, is provided along: another portion of the one side, of the display region D, along the terminal unit T; and three sides, of the display region D, not along the terminal unit T.

As illustrated in FIG. 12, the second dam wall Wb includes: a second metal protruding portion 27db provided to serve as the second wiring layer; the outer lower resin layer 28d formed of the same material as, and in the same layer as, the second planarization film 28a is, and provided on the second metal protruding portion 27db to serve as the second resin protruding portion; and the outer upper resin layer 32d formed of the same material as, and in the same layer as, the edge cover 32a, and provided above the outer lower resin layer 28d through the conductive layer 31b in order to serve as the fourth resin protruding portion. Here, the second metal protruding portion 27db is provided to electrically connect to either the first frame wire 21h or the second frame wire 21i. Moreover, the second metal protruding portion 27db illustrated in FIG. 12 includes: a lower metal film 24db made of such a film as a titanium film and provided toward the resin substrate layer 10; and an upper metal film 25db made of such a film as an aluminum film and provided toward the organic-EL-element layer 35. Furthermore, as illustrated in FIG. 12, the second metal protruding portion 27db has an end portion shaped into a forward tapered shape so that the lower metal film 24db protrudes further than the upper metal film 25db. Note that, similar to the second metal protruding portion 27d of the above first embodiment, the second metal protruding portion 27db, which is electrically connected to the first frame wire 21h, is provided along a portion of one side, of the display region D, along the terminal unit T. Moreover, similar to the second metal protruding portion 27d of the above first embodiment, the second metal protruding portion 27db, which is electrically connected to the second frame wire 21i, is provided along: another portion of the one side, of the display region D, along the terminal unit T; and three sides, of the display region D, not along the terminal unit T.

In addition, as illustrated in FIG. 12, the organic EL display device 50b includes a first metal layer 27eb in the frame region F. The first metal layer 27eb is shaped into a substantial C-shape, and provided between the trench G and the first slit Sa to serve as the second wiring layer. Here, as illustrated in FIG. 12, the first metal layer 27eb includes: a lower metal film 24eb; and an upper metal film 25eb, both of which are stacked on top of another in the stated order above the protective film 23a. The first metal layer 27eb is provided to be electrically connected to the second frame wire 21i through a contact hole formed in the first planarization film 22a and the protective film 23a. Note that, as illustrated in FIG. 12, the first metal layer 27eb has an end portion shaped into a forward tapered shape so that the lower metal film 24eb protrudes further than the upper metal film 25eb.

Moreover, similar to the organic EL display device 50a of the above first embodiment, the organic EL display device 50b includes a terminal metal layer 27fb in the frame region F. The terminal metal layer 27fb is equivalent to the terminal metal layer 27f of the organic EL display device 50a. Here, as illustrated in FIG. 13, the terminal metal layer 27fb includes: a lower metal film 24fb; and an upper metal film 25fb, both of which are stacked on top of another in the stated order above the protective film 23a. The terminal metal layer 27fb is provided to be electrically connected to the first frame wire 21h through a contact hole formed in the protective film 23a inside the trench G. Note that, as illustrated in FIG. 13, the terminal metal layer 27fb has an end portion shaped into a forward tapered shape so that the lower metal film 24fb protrudes further than the upper metal film 25fb. The end portion is covered with the second planarization film 28a. Such a feature improves contact between the end portion of the terminal metal layer 27fb and the second planarization film 28a. The improved contact can block intrusion of, for example, water into the display region D through a path; that is, an interface between the end portion of the terminal metal layer 27fb and the second planarization film 28a, thereby contributing to improvement in reliability of the organic EL display device 50b.

Moreover, as illustrated in FIGS. 12 and 13, the organic EL display device 50b includes the plurality of peripheral photo spacers 32b in the frame region F. The plurality of peripheral photo spacers 32b are shaped into islands, and protrude upwards at opposing edge portions of the trench G.

Similar to the organic EL display device 50a of the above first embodiment, the organic EL display device 50b is flexible, and allows, in each of the sub pixels P, the light-emitting layer 3 of the organic EL layer 33 to appropriately emit light through the first TFT 9a, the second TFT 9b, and the third TFT 9c to display an image.

The organic EL display device 50b of this embodiment can be produced as follows: at the TFT layer forming step of a method for producing the organic EL display device 50a of the above first embodiment, the metal multilayer film for forming the second wiring layer is changed from a three-layer film (a titanium film (upper)/an aluminum film (intermediate)/a titanium film (lower)) to a two-layer film (an aluminum film (upper)/a titanium film (lower)). Here, when the two-layer (an aluminum film (upper)/a titanium film (lower)) metal multilayer film is patterned, a resist pattern is formed on the metal multilayer film. Using the resist pattern, the metal multilayer is wet-etched. Here, as to an end portion of the second wiring layer, a line width of the aluminum film (upper) is smaller than a line width of the titanium film (lower) because of a difference in etching rate. As illustrated in FIG. 13, an end portion of the second wiring layer including the terminal metal layer 27fb is shaped into a forward tapered shape.

As described above, as to the organic EL display device 50b of this embodiment, the TFT layer 30b includes: the first electrode layer including the gate lines 14d; the first interlayer insulating film 15; the second electrode layer including the upper wiring layer 16a; the second interlayer insulating film 17; the first wiring layer including the source lines 21f; the first planarization film 22a; the protective film 23a; the second wiring layer including the power supply line 27ab; and the second planarization film 28a, all of which are stacked on top of another in the stated order. Here, in the frame region F around the display region D, the first frame wire 21h is provided to extend to the terminal unit T to serve as the first wiring layer. The first frame wire 21h is electrically connected to the power supply line 27ab toward the display region D. Moreover, in the frame region F, the second frame wire 21i is provided to extend to the terminal unit T to serve as the first wiring layer. The first frame wire 21i is electrically connected, through the conductive layer 31b, to the second electrode 34 toward the display region D. Furthermore, the first planarization film 22a and the second planarization film 28a include the first slit Sa shaped into a frame, provided between the display region D and the first dam wall Wa, and penetrating the first planarization film 22a and the second planarization film 28a. The first dam wall Wa overlaps with the peripheral end portion of the organic sealing film 37. In addition, around the first dam wall Wa, the second dam wall Wb is provided in the shape of a frame. Moreover, the second planarization film 28a includes the second slit Sb shaped into a frame, provided between the first dam wall Wa and the second dam wall Wb, and penetrating the second planarization film 28a. Then, in the first slit Sa and the second slit Sb, the first frame wire 21h and the second frame wire 21i have respective edge portions facing each other and covered with the protective film 23a. Hence, even if the first slit Sa and the second slit Sb are formed, the first dam wall Wa and the second dam wall Wb keep the first frame wire 21h and the second frame wire 21i from damage caused by side-etching with a developer to be used for forming the first planarization film 22a and the second planarization film 28a, an etchant to be used for forming the first electrodes 31a, and a developer to be used for forming the edge cover 32a. Such a feature can reduce the damage to the first frame wire 21h and the second frame wire 21i during the production steps of these wires. Moreover, the damage to the first frame wire 21h and the second frame wire 21i is reduced during the production steps of these wires, thereby making it possible to ensure sealing capability of the sealing film 40 formed above the first frame wire 21h and the second frame wire 2ii. Such features can reduce deterioration of the organic EL layers 33, thereby contributing to improvement in reliability of the organic EL display device 50b.

Moreover, as to the organic EL display device 50b of this embodiment, the first dam wall Wa includes the first metal protruding portion 27cb, and the second dam wall Wb includes the second metal protruding portion 27db. Thanks to such a feature, the first dam wall Wa and the second dam wall Wb are formed tall, and can block ink that forms the organic sealing film 37.

Furthermore, as to the organic EL display device 50b of this embodiment, the trench G, which is shaped into a frame and penetrates the first planarization film 22a and the second planarization film 28a, is provided around the display region D. Such a feature can keep water from moving to the display region D through the inside of such resin layers as the first planarization film 22a and the second planarization film 28a. As a result, the organic EL layers 33 can be kept from deterioration.

In addition, as to the organic EL display device 50b of this embodiment, the first metal protruding portion 27cb and the second metal protruding portion 27db are provided to electrically connect to either the first frame wire 21h or the second frame wire 21i. Such a feature can reduce wiring resistance of the first frame wire 21h and the second frame wire 21i.

Moreover, as to the organic EL display device 50b of this embodiment, the first metal layer 27eb is provided to electrically connect to the second frame wire 21i. Such a feature can reduce wiring resistance of the second frame wire 21i.

Furthermore, as to the organic EL display device 50b of this embodiment, the terminal metal layer 27fb is provided to electrically connect to the first frame wire 21h. Such a feature can reduce wiring resistance of the first frame wire 21h.

In addition, as to the organic EL display device 50b of this embodiment, the surface of the first planarization film 22a is covered with the protective film 23a. Such a feature can keep the surface layer of the first planarization film 22a from being etched when, for example, the second wiring layer including the power supply line 27a is patterned by dry etching. As a result, the interior of the chamber of a dry etching apparatus can be kept from contamination.

### Third Embodiment

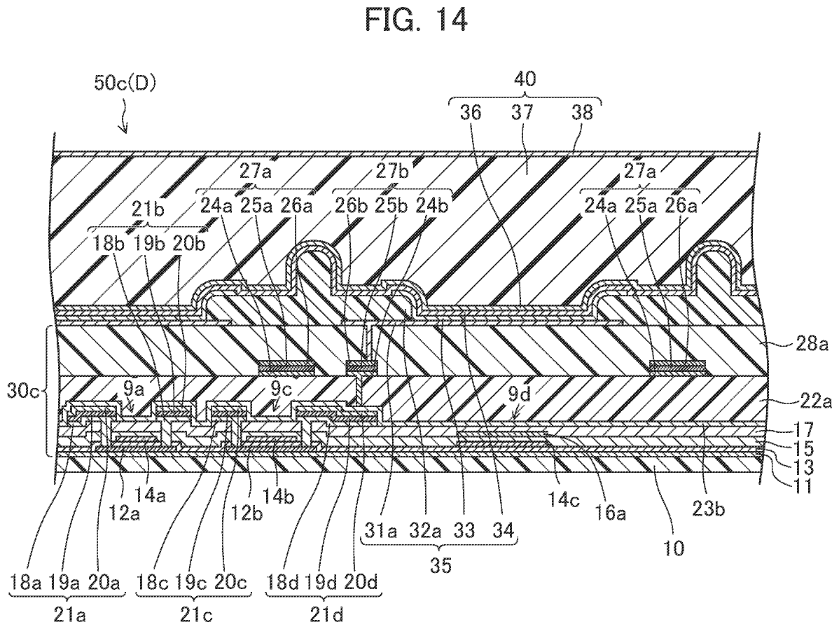

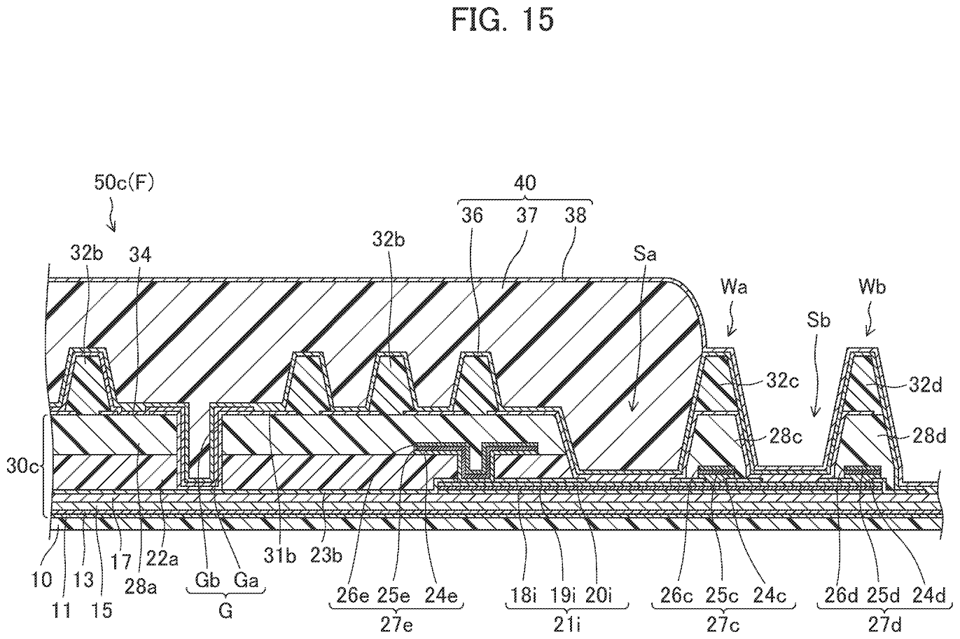

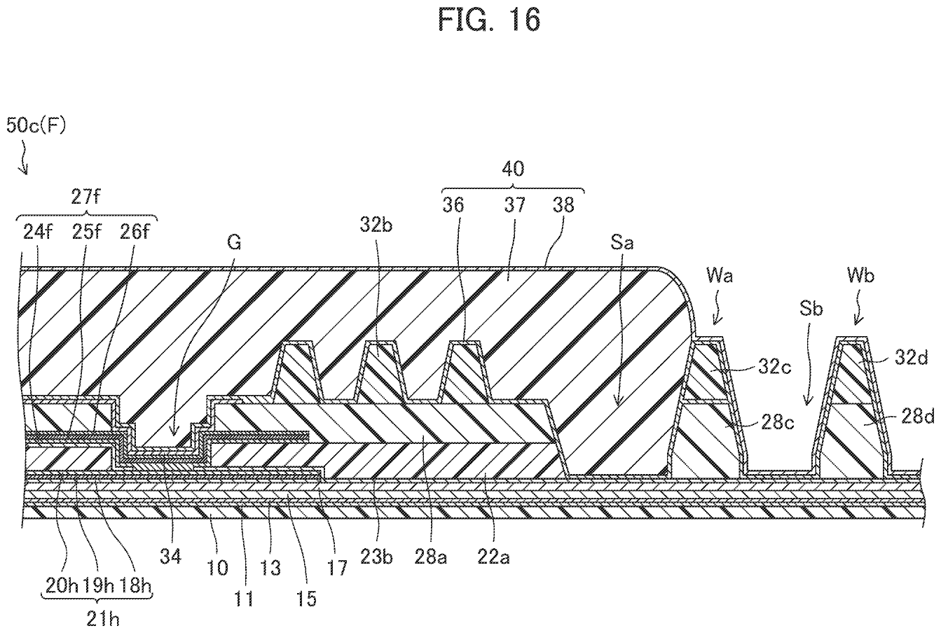

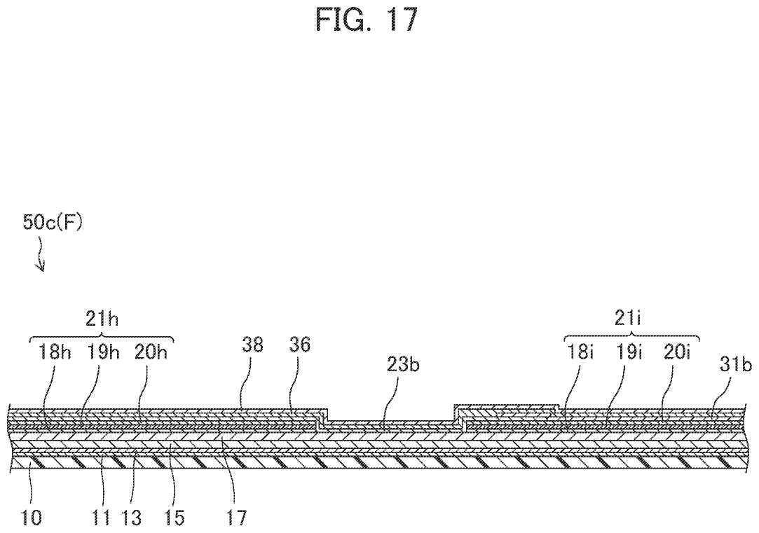

FIGS. 14 to 17 illustrate a third embodiment of a display device according to the present invention. Here, FIG. 14 is a cross-sectional view of the display region D in an organic EL display device 50c of this embodiment. FIG. 14 corresponds to FIG. 4. Moreover, FIGS. 15, 16, and 17 are cross-sectional views of the frame region F in the organic EL display device 50c. FIG. 15, FIG. 16, and FIG. 17 respectively correspond to FIG. 7, FIG. 8, and FIG. 9.

The above first embodiment exemplifies the organic EL display device 50a including the protective film 23a provided between the first planarization film 22a and the second wiring layer. Whereas, this embodiment exemplifies the organic EL display device 50c including a protective film 23b provided between the first wiring layer and the first planarization film 22a.

Similar to the organic EL display device 50a of the above first embodiment, the organic EL display device 50c includes: the display region D; and the frame region F provided around the display region D. Moreover, as illustrated in FIG. 14, the organic EL display device 50c includes: the resin substrate layer 10; a TFT layer 30c provided on the resin substrate layer 10; the organic-EL-element layer 35 provided on the TFT layer 30c; and the sealing film 40 provided to cover the organic-EL-element layer 35.

Similar to the TFT layer 30a of the above first embodiment, the TFT layer 30c illustrated in FIG. 14 includes: the base coat film 11 provided on the resin substrate layer 10; and the plurality of first TFTs 9a, the plurality of second TFT 9b, the plurality of third TFTs 9c, and the plurality of capacitors 9d all of which are provided on the base coat film 11. Moreover, the TFT layer 30c in FIG. 14 includes: the protective film 23b; the first planarization film 22a; and the second planarization film 28a, all of which are provided in the stated order above the first TFTs 9a, the second TFTs 9b, the third TFTs 9c, and the capacitors 9d.

The TFT layer 30c illustrated in FIG. 14 includes: the semiconductor layers 12a and 12b; the gate insulating film 13; the gate electrodes 14a and 14b and the lower wiring layer 14c (the first electrode layer); the first interlayer insulating film 15; the upper wiring layer 16a (the second electrode layer); the second interlayer insulating film 17, the source electrodes 21a and 21c and the drain electrodes 21b and 21d (the first wiring layer); the protective film 23b formed of an inorganic insulating film; the first planarization film 22a; the power supply line 27a and the relay electrode 27b (the second wiring layer); and the second planarization film 28a, all of which are stacked on top of another in the stated order above the base coat film 11.

Similar to the TFT layer 30a of the above first embodiment, the TFT layer 30c includes the plurality of gate lines 14d in the display region D extending in parallel with one another. Moreover, similar to the TFT layer 30a of the above first embodiment, the TFT layer 30c includes the plurality of light-emission control lines 14e in the display region D extending in parallel with one another. Furthermore, similar to the TFT layer 30a of the above first embodiment, the TFT layer 30c includes the plurality of source lines 21f in the display region D extending in parallel with one another. In addition, the TFT layer 30c includes the power supply line 27a in display region D provided in a grid form and serving as the second wiring layer. Moreover, in the TFT layer 30c, similar to the TFT layer 30a of the above first embodiment, each of the sub-pixels P includes a first TFT 9a, a second TFT 9b, a third TFT 9c, and a capacitor 9d. Moreover, in the TFT layer 30c, the drain electrode 21d of the third TFT 9c illustrated in FIG. 14 is electrically connected to the relay electrode 27b through a contact hole formed in the protective film 23b and the first planarization film 22a. Furthermore, in the TFT layer 30c, the upper wiring layer 16a of the capacitor 9d is electrically connected to the power supply line 27a through a not-shown contact hole formed in the second interlayer insulating film 17, the protective film 23b, and the first planarization film 22a.

In addition, similar to the organic EL display device 50a of the above first embodiment, the organic EL display device 50c also includes the first frame wire 21h and the second frame wire 21i in the frame region F.

Moreover, similar to the organic EL display device 50a of the above first embodiment, the organic EL display device 50c illustrated in FIGS. 15 and 16 includes the first dam wall Wa and the second dam wall Wb in the frame region F. Here, the first slit Sa is provided between the display region D and the first dam wall Wa, and the second slit Sb is provided between the first dam wall Wa and the second dam wall Wb. In the first slit Sa and the second slit Sb, as illustrated in FIG. 17, the first frame wire 21h and the second frame wire 21i have respective edge portions facing each other and covered with the protective film 23b.

Furthermore, similar to the organic EL display device 50a of the above first embodiment, the organic EL display device 50c, as illustrated in FIG. 15, includes the first metal layer 27e in the frame region F. The first metal layer 27e is shaped into a substantial C-shape, and provided between the trench G and the first slit Sa to serve as the second wiring layer.

In addition, similar to the organic EL display device 50a of the above first embodiment, the organic EL display device 50c includes the terminal metal layer 27f in the frame region F. The terminal metal layer 27f is shaped into a substantial T-shape, and serves as the second wiring layer. Here, as illustrated in FIG. 16, the terminal metal layer 27f includes: the lower metal film 24f; the intermediate metal film 25f; and the upper metal film 26f, all of which are stacked on top of another in the stated order above the first planarization film 22a. The terminal metal layer 27f is provided to be electrically connected to the first frame wire 21h through a contact hole formed in the protective film 23b inside the trench G.

Moreover, similar to the organic EL display device 50a of the above first embodiment, the organic EL display device 50c, as illustrated in FIGS. 15 and 16, includes the plurality of peripheral photo spacers 32b in the frame region F. The plurality of peripheral photo spacers 32b are shaped into islands, and protrude upwards at opposing edge portions of the trench G.

Similar to the organic EL display device 50a of the above first embodiment, the organic EL display device 50c is flexible, and allows, in each of the sub-pixels P, the light-emitting layer 3 of the organic EL layer 33 to appropriately emit light through the first TFT 9a, the second TFT 9b, and the third TFT 9c to display an image.

The organic EL display device 50c of this embodiment can be produced as follows: at the TFT layer forming step of a method for producing the organic EL display device 50a in the above embodiment, a step of forming the protective film 23a is carried out between a step of forming the first wiring layer and a step of forming the first planarization film 22a.

As described above, as to the organic EL display device 50c of this embodiment, the TFT layer 30c includes: the first electrode layer including the gate lines 14d; the first interlayer insulating film 15; the second electrode layer including the upper wiring layer 16a; the second interlayer insulating film 17; the first wiring layer including the source lines 21f; the protective film 23b; the first planarization film 22a; the second wiring layer including the power supply line 27a; and the second planarization film 28a, all of which are stacked on top of another in the stated order. Here, in the frame region F around the display region D, the first frame wire 21h is provided to extend to the terminal unit T to serve as the first wiring layer. The first frame wire 21h is electrically connected to the power supply line 27a toward the display region D. Moreover, in the frame region F, the second frame wire 21i is provided to extend to the terminal unit T to serve as the first wiring layer. The first frame wire 21i is electrically connected, through the conductive layer 31b, to the second electrode 34 toward the display region D. Furthermore, the first planarization film 22a and the second planarization film 28a include the first slit Sa shaped into a frame, provided between the display region D and the first dam wall Wa, and penetrating the first planarization film 22a and the second planarization film 28a. The first dam wall Wa overlaps with the peripheral end portion of the organic sealing film 37. In addition, around the first dam wall Wa, the second dam wall Wb is provided in the shape of a frame. Moreover, the second planarization film 28a includes the second slit Sb shaped into a frame, provided between the first dam wall Wa and the second dam wall Wb, and penetrating the second planarization film 28a. Then, in the first slit Sa and the second slit Sb, the first frame wire 21h and the second frame wire 21i have respective edge portions facing each other and covered with the protective film 23b. Hence, even if the first slit Sa and the second slit Sb are formed, the first dam wall Wa and the second dam wall Wb keep the first frame wire 21h and the second frame wire 21i from damage caused by side-etching with a developer to be used for forming the first planarization film 22a and the second planarization film 28a, an etchant to be used for forming the first electrodes 31a, and a developer to be used for forming the edge cover 32a. Such a feature can reduce the damage to the first frame wire 21h and the second frame wire 21i during the production steps of these wires. Moreover, the damage to the first frame wire 21h and the second frame wire 21i is reduced during the production steps of these wires, thereby making it possible to ensure sealing capability of the sealing film 40 formed above the first frame wire 21h and the second frame wire 21i. Such features can reduce deterioration of the organic EL layers 33, thereby contributing to improvement in reliability of the organic EL display device 50c.

Furthermore, as to the organic EL display device 50c of this embodiment, the first dam wall Wa includes the first metal protruding portion 27c, and the second dam wall Wb includes the second metal protruding portion 27d. Thanks to such a feature, the first dam wall Wa and the second dam wall Wb are formed tall, and can block ink that forms the organic sealing film 37.

In addition, as to the organic EL display device 50c of this embodiment, the trench G, which is shaped into a frame and penetrates the first planarization film 22a and the second planarization film 28a, is provided around the display region D. Such a feature can keep water from moving to the display region D through the inside of such resin layers as the first planarization film 22a and the second planarization film 28a. As a result, the organic EL layers 33 can be kept from deterioration.

Moreover, as to the organic EL display device 50c of this embodiment, the first metal protruding portion 27c and the second metal protruding portion 27d are provided to electrically connect to either the first frame wire 21h or the second frame wire 21i. Such a feature can reduce wiring resistance of the first frame wire 21h and the second frame wire 21i.

Furthermore, as to the organic EL display device 50c of this embodiment, the first metal layer 27e is provided to electrically connect to the second frame wire 21i. Such a feature can reduce wiring resistance of the second frame wire 21i.

In addition, as to the organic EL display device 50c of this embodiment, the terminal metal layer 27f is provided to electrically connect to the first frame wire 21h. Such a feature can reduce wiring resistance of the first frame wire 21h.

### Fourth Embodiment

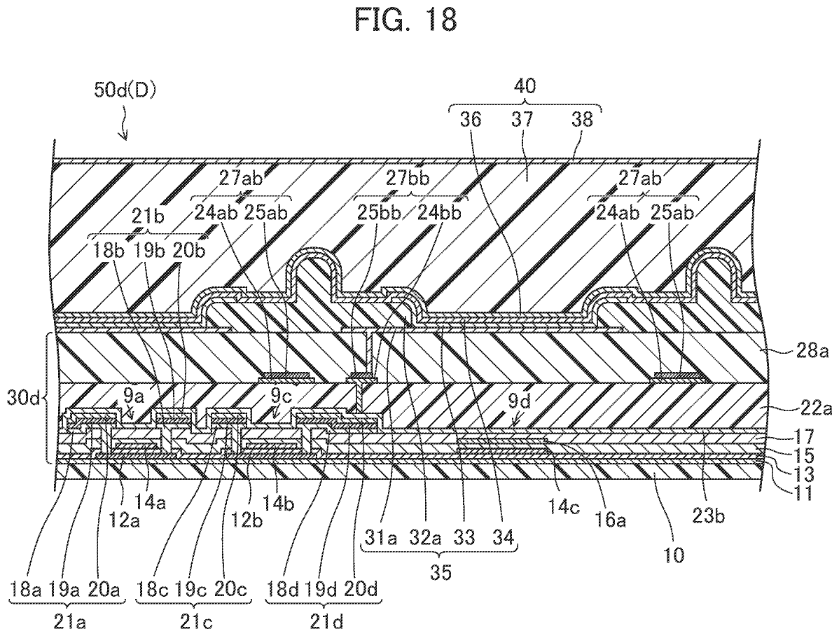

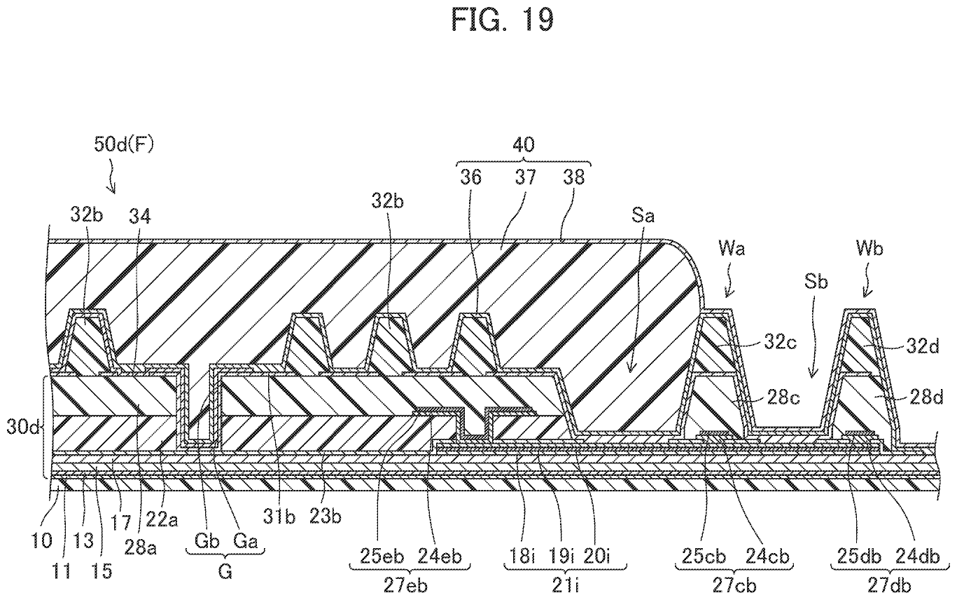

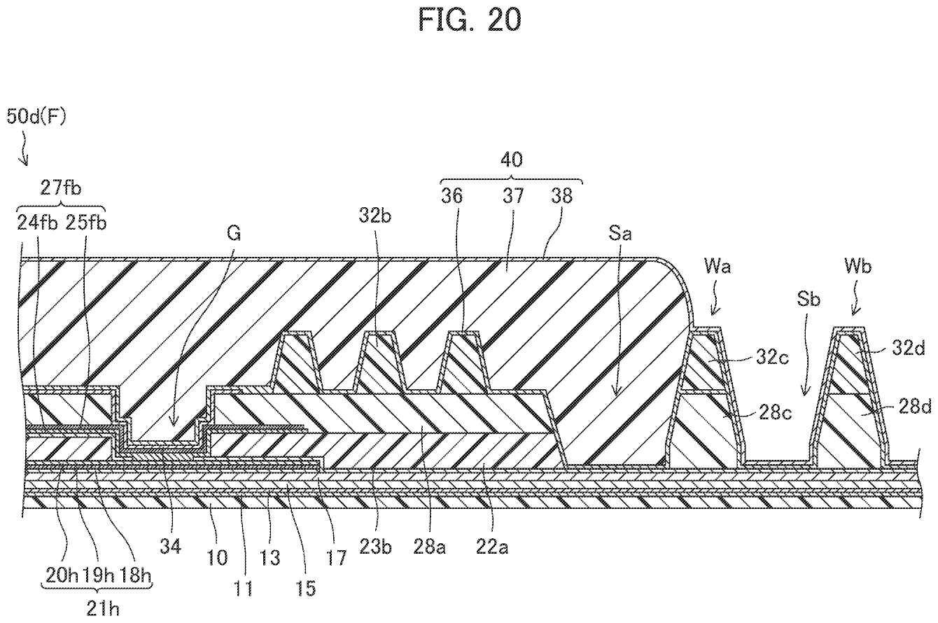

FIGS. 18 to 20 illustrate a fourth embodiment of a display device according to the present invention. Here, FIG. 18 is a cross-sectional view of the display region D in an organic EL display device 50d of this embodiment. FIG. 18 corresponds to FIG. 4. Moreover, FIGS. 19 and 20 are cross-sectional views of the frame region F in the organic EL display device 50d. FIG. 19 and FIG. 20 respectively correspond to FIG. 7 and FIG. 8.

The above first embodiment exemplifies the organic EL display device 50a including the protective film 23a provided between the first planarization film 22a and the second wiring layer. Whereas, this embodiment exemplifies the organic EL display device 50d including: the protective film 23b provided between the first wiring layer and the first planarization film 22a; and the second wiring layer made of a multilayer film having two layers.

Similar to the organic EL display device 50a of the above first embodiment, the organic EL display device 50d includes: the display region D; and the frame region F provided around the display region D. Moreover, as illustrated in FIG. 18, the organic EL display device 50d includes: the resin substrate layer 10; a TFT layer 30d provided on the resin substrate layer 10; the organic-EL-element layer 35 provided on the TFT layer 30d; and the sealing film 40 provided to cover the organic-EL-element layer 35.

Similar to the TFT layer 30a of the above first embodiment, the TFT layer 30d illustrated in FIG. 18 includes: the base coat film 11 provided on the resin substrate layer 10; and the plurality of first TFTs 9a, the plurality of second TFT 9b, the plurality of third TFTs 9c, and the plurality of capacitors 9d all of which are provided on the base coat film 11. Moreover, the TFT layer 30d in FIG. 18 includes: the protective film 23b; the first planarization film 22a; and the second planarization film 28a, all of which are provided in the stated order above the first TFTs 9a, the second TFTs 9b, the third TFTs 9c, and the capacitors 9d.

The TFT layer 30d in FIG. 18 includes: the semiconductor layers 12a and 12b; the gate insulating film 13: the gate electrodes 14a and 14b and the lower wiring layer 14c (the first electrode layer); the first interlayer insulating film 15; the upper wiring layer 16a (the second electrode layer); the second interlayer insulating film 17; the source electrodes 21a and 21c and the drain electrodes 21b and 21d (the first wiring layer); the protective film 23a; the first planarization film 22a; the power supply line 27ab and the relay electrode 27bb (the second wiring layer); and the second planarization film 28a, all of which are stacked on top of another in the stated order above the base coat film 11.

Similar to the TFT layer 30a of the above first embodiment, the TFT layer 30d includes the plurality of gate lines 14d in the display region D extending in parallel with one another. Moreover, similar to the TFT layer 30a of the above first embodiment, the TFT layer 30d includes the plurality of light-emission control lines 14e in the display region D extending in parallel with one another. Furthermore, similar to the TFT layer 30a of the above first embodiment, the TFT layer 30d includes the plurality of source lines 21f in the display region D extending in parallel with one another. In addition, the TFT layer 30d includes the power supply line 27ab in display region D provided in a grid form and serving as the second wiring layer. Moreover, in the TFT layer 30d, similar to the TFT layer 30a of the above first embodiment, each of the sub-pixels P includes a first TFT 9a, a second TFT 9b, a third TFT 9c, and a capacitor 9d. Furthermore, in the TFT layer 30d, the second TFT 9b in each sub-pixel P is electrically connected to the corresponding first TFT 9a, power supply line 27ab, and third TFT 9c. In addition, in the TFT layer 30d, the third TFT 9c in each sub-pixel P is electrically connected to the corresponding second TFT 9a, power supply line 27ab, and light-emission control line 14e. Moreover, in the TFT layer 30d, the drain electrode 21d of the third TFT 9c illustrated in FIG. 18 is electrically connected to the relay electrode 27bb through a contact hole formed in the protective film 23b and the first planarization film 22a. Furthermore, in the TFT layer 30d, the capacitor 9d in each sub-pixel P is electrically connected to the corresponding first TFT 9a and power supply line 27ab.

In addition, similar to the organic EL display device 50a of the above first embodiment, the organic EL display device 50d also includes the first frame wire 21h and the second frame wire 21i in the frame region F.

Moreover, similar to the organic EL display device 50b of the above second embodiment, the organic EL display device 50d illustrated in FIGS. 19 and 20 includes the first dam wall Wa and the second dam wall Wb in the frame region F. Here, the first slit Sa is provided between the display region D and the first dam wall Wa, and the second slit Sb is provided between the first dam wall Wa and the second dam wall Wb. In the first slit Sa and the second slit Sb, the first frame wire 21h and the second frame wire 21i have respective edge portions facing each other and covered with the protective film 23b.

Furthermore, similar to the organic EL display device 50b of the above second embodiment, the organic EL display device 50d includes, as illustrated in FIG. 19, the first metal layer 27eb in the frame region F. The first metal layer 27eb is shaped into a substantial C-shape, and provided between the trench G and the first slit Sa to serve as the second wiring layer.

In addition, similar to the organic EL display device 50b of the above second embodiment, the organic EL display device 50d includes the terminal metal layer 27fb in the frame region F. The terminal metal layer 27fb serves as the second wiring layer. Here, as illustrated in FIG. 20, the terminal metal layer 27fb includes: the lower metal film 24fb; and the upper metal film 25fb, both of which are stacked on top of another in the stated order above the first planarization film 22a. The terminal metal layer 27fb is provided to be electrically connected to the first frame wire 21h through a contact hole formed in the protective film 23b inside the trench G. Note that, as illustrated in FIG. 20, the terminal metal layer 27fb has an end portion shaped into a forward tapered shape so that the lower metal film 24fb protrudes further than the upper metal film 25fb. The end portion is covered with the second planarization film 28a. Such a feature improves contact between the end portion of the terminal metal layer 27fb and the second planarization film 28a. The improved contact can block intrusion of, for example, water into the display region D through a path, that is, an interface between the end portion of the terminal metal layer 27fb and the second planarization film 28a, thereby contributing to improvement in reliability of the organic EL display device 50d.

Moreover, similar to the organic EL display device 50a of the above first embodiment, the organic EL display device 50d, as illustrated in FIGS. 19 and 20, includes the plurality of peripheral photo spacers 32b in the frame region F. The plurality of peripheral photo spacers 32b are shaped into islands, and protrude upwards at opposing edge portions of the trench G.

Similar to the organic EL display device 50a of the above first embodiment, the organic EL display device 50d is flexible, and allows, in each of the sub-pixels P, the light-emitting layer 3 of the organic EL layer 33 to appropriately emit light through the first TFT 9a, the second TFT 9b, and the third TFT 9c to display an image.

The organic EL display device 50d of this embodiment can be produced as follows: at the TFT layer forming step of a method for producing the organic EL display device 50a of the above first embodiment, the metal multilayer film for forming the second wiring layer is changed from a three-layer film (a titanium film (upper)/an aluminum film (intermediate)/a titanium film (lower)) to a two-layer film (an aluminum film (upper)/a titanium film (lower)) as seen in the above second embodiment, and a step of forming the protective film 23a is carried out between a step of forming the first wiring layer and a step of forming the first planarization film 22a

As described above, as to the organic EL display device 50d of this embodiment, the TFT layer 30d includes: the first electrode layer including the gate lines 14d; the first interlayer insulating film 15; the second electrode layer including the upper wiring layer 16a; the second interlayer insulating film 17; the first wiring layer including the source lines 21f; the protective film 23b; the first planarization film 22a; the second wiring layer including the power supply line 27ab; and the second planarization film 28a, all of which are stacked on top of another in the stated order. Here, in the frame region F around the display region D, the first frame wire 21h is provided to extend to the terminal unit T and to serve as the first wiring layer. The first frame wire 21h is electrically connected to the power supply line 27ab toward the display region D. Moreover, in the frame region F, the second frame wire 21i is provided to extend to the terminal unit T and to serve as the first wiring layer. The first frame wire 21i is electrically connected, through the conductive layer 31b, to the second electrode 34 toward the display region D. Furthermore, the first planarization film 22a and the second planarization film 28a include the first slit Sa shaped into a frame, provided between the display region D and the first dam wall Wa, and penetrating the first planarization film 22a and the second planarization film 28a. The first dam wall Wa overlaps with the peripheral end portion of the organic sealing film 37. In addition, around the first dam wall Wa, the second dam wall Wb is provided in the shape of a frame. Moreover, the second planarization film 28a includes the second slit Sb shaped into a frame, provided between the first dam wall Wa and the second dam wall Wb, and penetrating the second planarization film 28a. Then, in each of the first slit Sa and the second slit Sb, the first frame wire 21h and the second frame wire 21i have respective edge portions facing each other and covered with the protective film 23b. Hence, even if the first slit Sa and the second slit Sb are formed, the first dam wall Wa and the second dam wall Wb keep the first frame wire 21h and the second frame wire 21i from damage caused by side-etching with a developer to be used for forming the first planarization film 22a and the second planarization film 28a, an etchant to be used for forming the first electrodes 31a, and a developer to be used for forming the edge cover 32a. Such a feature can reduce the damage to the first frame wire 21h and the second frame wire 21i during the production steps of these wires. Moreover, the damage to the first frame wire 21h and the second frame wire 21i is reduced during the production steps of these wires, thereby making it possible to ensure sealing capability of the sealing film 40 formed above the first frame wire 21h and the second frame wire 21i. Such features can reduce deterioration of the organic EL layers 33, thereby contributing to improvement in reliability of the organic EL display device 50d.

Furthermore, as to the organic EL display device 50d of this embodiment, the first dam wall Wa includes the first metal protruding portion 27cb, and the second dam wall Wb includes the second metal protruding portion 27db. Thanks to such a feature, the first dam wall Wa and the second dam wall Wb are formed tall, and can block ink that forms the organic sealing film 37.

In addition, as to the organic EL display device 50d of this embodiment, the trench G, which is shaped into a frame and penetrates the first planarization film 22a and the second planarization film 28a, is provided around the display region D. Such a feature can keep water from moving to the display region D through the inside of such resin layers as the first planarization film 22a and the second planarization film 28a. As a result, the organic EL layers 33 can be kept from deterioration.

Moreover, as to the organic EL display device 50d of this embodiment, the first metal protruding portion 27cb and the second metal protruding portion 27db are provided to electrically connect to either the first frame wire 21h or the second frame wire 21i. Such a feature can reduce wiring resistance of the first frame wire 21h and the second frame wire 21i.

Furthermore, as to the organic EL display device 50d of this embodiment, the first metal layer 27eb is provided to electrically connect to the second frame wire 21i. Such a feature can reduce wiring resistance of the second frame wire 21i.

In addition, as to the organic EL display device 50d of this embodiment, the terminal metal layer 27fb is provided to electrically connect to the first frame wire 21h. Such a feature can reduce wiring resistance of the first frame wire 21h.

Moreover, as to the organic EL display device 50d of this embodiment, the terminal metal layer 27fb includes: the lower metal film 24fb made of a titanium film and provided toward the resin substrate layer 10; and the upper metal film 25fb made of an aluminum film and provided toward the organic-EL-element layer 35. Here, the terminal metal layer 27fb has an end portion shaped into a forward tapered shape so that the lower metal film 24fb protrudes further than the upper metal film 25fb. The end portion is covered with the second planarization film 28a. Such a feature improves contact between the end portion of the terminal metal layer 27fb and the second planarization film 28a. The improved contact can block intrusion of, for example, water into the display region D through a path; that is, an interface between the end portion of the terminal metal layer 27fb and the second planarization film 28a, thereby contributing to improvement in reliability of the organic EL display device 50d.

### Fifth Embodiment

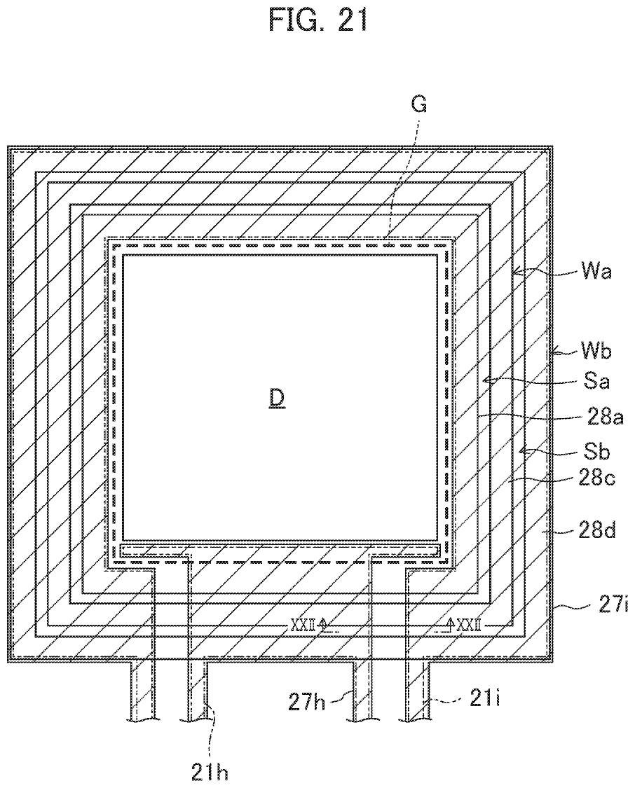

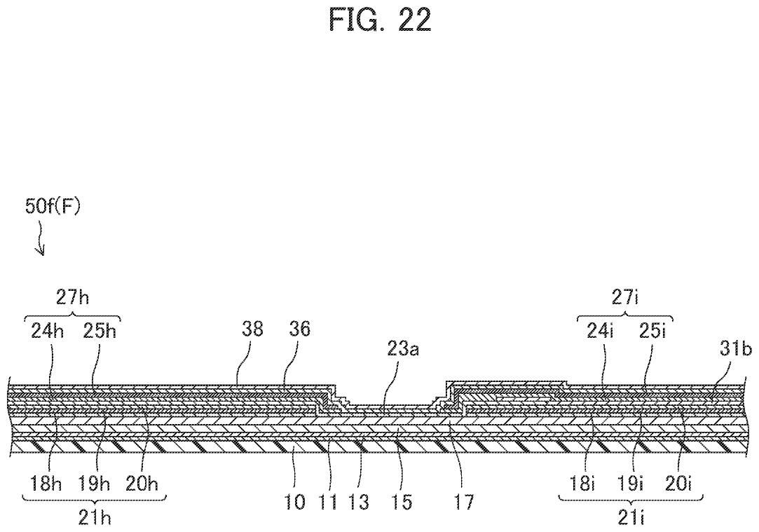

FIGS. 21 and 22 illustrate a fifth embodiment of a display device according to the present invention. Here, FIG. 21 is a plan view of an organic EL display device 50d according to this embodiment. The plan view schematically shows an arrangement of, for example, the first frame wire 21h, the second frame wire 21i, the trench G, the first dam wall Wa, and the second dam wall Wb. FIG. 21 corresponds to FIG. 2. Moreover, FIG. 22 is a cross-sectional view of the frame region F in the organic EL display device 50f, taken from line XXII-XXII in FIG. 21.

The above first embodiment exemplifies the organic EL display device 50a in which: the first metal protruding portion 27c having a relatively narrow width, the second metal protruding portion 27d, and the terminal metal layer 27f are electrically connected to the first frame wire 21h; and the first metal protruding portion 27c having a relatively narrow width, the second metal protruding portion 27d, and the first metal layer 27e are electrically connected to the fecund frame wire 21i. Whereas, this embodiment exemplifies the organic EL display device 50f in which: a second metal layer 27h having a relatively wide width is electrically connected to the first frame wire 21h; and a third metal layer 27i having a relatively wide width is electrically connected to the second frame wire 21i.

Similar to the organic EL display device 50a of the above first embodiment, the organic EL display device 50f includes: the display region D; and the frame region F provided around the display region D. Moreover, similar to the organic EL display device 50b of the above second embodiment, the organic EL display device 50f includes: the resin substrate layer 10; the TFT layer 30b provided on the resin substrate layer 10; the organic-EL-element layer 35 provided on the TFT layer 30b; and the sealing film 40 provided to cover the organic-EL-element layer 35.

Similar to the organic EL display device 50a of the above first embodiment, the organic EL display device 50f also includes the first frame wire 21h and the second frame wire 21i in the frame region F. Here, as illustrated in FIG. 21, the organic EL display device 50f includes the metal layer 27h covering the first frame wire 21h, and the third metal layer 27i covering the second frame wire 21i. Then, as illustrated in FIG. 22, the protective film 23a having a contact hole is provided between the second and third metal layers 27h and 27i and between the first and second frame wires 21h and 21i. Hence, the second metal layer 27h and the first frame wire 21h are electrically connected to each other, and the third metal layer 27i and the second frame wire 21i are electrically connected to each other. Note that this embodiment exemplifies the case where the protective film 23a is provided between the second and third metal layers 27h and 27i and between the first and second frame wires 21h and 21i. However, the protective film 23a may be omitted. Moreover, as illustrated in FIG. 22, the second metal layer 27h includes: a lower metal film 24h made of such a film as a titanium film and provided toward the resin substrate layer 10; and an upper metal film 25h made of such a film as an aluminum film and provided toward the organic-EL-element layer 35. Furthermore, as illustrated in FIG. 22, the second metal layer 27h has an end portion shaped into a forward tapered shape so that the lower metal film 24h protrudes further than the upper metal film 25h. In addition, as illustrated in FIG. 22, the third metal layer 27i includes: a lower metal film 24i made of such a film as a titanium film and provided toward the resin substrate layer 10; and an upper metal film 25i made of such a film as an aluminum film and provided toward the organic-EL-element layer 35. Moreover, as illustrated in FIG. 22, the third metal layer 27i has an end portion shaped into a forward tapered shape so that the lower metal film 24i protrudes further than the upper metal film 25i.

Furthermore, similar to the organic EL display device 50a of the above first embodiment, the organic EL display device 50f includes the first dam wall Wa and the second dam wall Wb in the frame region F.

In addition, similar to the organic EL display device 50a of the above first embodiment, the organic EL display device 50f includes the plurality of peripheral photo spacers 32b in the frame region F. The plurality of peripheral photo spacers 32b are shaped into islands, and protrude upwards at opposing edge portions of the trench G.

Similar to the organic EL display device 50a of the above first embodiment, the organic EL display device 50f is flexible, and allows, in each of the sub-pixels P, the light-emitting layer 3 of the organic EL layer 33 to appropriately emit light through the first TFT 9a, the second TFT 9b, and the third TFT 9c to display an image.

The organic EL display device 50f of this embodiment can be produced as follows: at the TFT layer forming step of a method for producing the organic EL display device 50a of the above first embodiment, the metal multilayer film for forming the second wiring layer is changed from a three-layer film (a titanium film (upper)/an aluminum film (intermediate)/a titanium film (lower)) to a two-layer film (an aluminum film (upper)/a titanium film (lower)), and patterned in a different shape.

As described above, as to the organic EL display device 50f of this embodiment, the TFT layer 30b includes: the first electrode layer including the gate lines 14d; the first interlayer insulating film 15; the second electrode layer including the upper wiring layer 16a; the second interlayer insulating film 17; the first wiring layer including the source lines 21f; the first planarization film 22a; the protective film 23a; the second wiring layer including the power supply line 27ab; and the second planarization film 28a, all of which are stacked on top of another in the stated order. Here, in the frame region F around the display region D, the first frame wire 21h is provided to extend to the terminal unit T and to serve as the first wiring layer. The first frame wire 21h is electrically connected to the power supply line 27ab toward the display region D. Moreover, in the frame region F, the second frame wire 21i is provided to extend to the terminal unit T and to serve as the first wiring layer. The first frame wire 21i is electrically connected, through the conductive layer 31b, to the second electrode 34 toward the display region D. Furthermore, the first planarization film 22a and the second planarization film 28a include the first slit Sa shaped into a frame, provided between the display region D and the first dam wall Wa, and penetrating the first planarization film 22a and the second planarization film 28a. The first dam wall Wa overlaps with the peripheral end portion of the organic sealing film 37. In addition, around the first dam wall Wa, the second dam wall Wb is provided in the shape of a frame. Moreover, the second planarization film 28a includes the second slit Sb shaped into a frame, provided between the first dam wall Wa and the second dam wall Wb, and penetrating the second planarization film 28a. Then, in the first slit Sa and the second slit Sb, the first frame wire 21h and the second frame wire 21i have respective edge portions facing each other and covered with the protective film 23a. Hence, even if the first slit Sa and the second slit Sb are formed, the first dam wall Wa and the second dam wall Wb keep the first frame wire 21h and the second frame wire 21i from damage caused by side-etching with a developer to be used for forming the first planarization film 22a and the second planarization film 28a, an etchant to be used for forming the first electrodes 31a, and a developer to be used for forming the edge cover 32a. Such a feature can reduce the damage to the first frame wire 21h and the second frame wire 21i during the production steps of these wires. Furthermore, the second metal layer 27h and the third metal layer 27i include: the lower metal films 24h and 24i made of titanium films and provided toward the resin substrate layer 10; and the upper metal films 25h and 251 made of aluminum films and provided toward the organic-EL-element layer 35. Hence, because of the developer to be used for forming the second planarization film 28a, the etchant to be used for forming the first electrodes 31a, and the developer to be used for forming the edge cover 32a, the end portions of the second metal layer 27h and the third metal layer 27i are each shaped into a forward tapered shape so that, in each of the end portions of the second metal layer 27h and the third metal layer 27i, the lower metal film protrudes further than the upper metal film. Such a feature makes it possible to ensure sealing capability of the sealing film 40 formed above the second metal layer 27h and the third metal layer 27i. This sealing capability can reduce deterioration of the organic EL layers 33, thereby contributing to improvement in reliability of the organic EL display device 50f.

In addition, as to the organic EL display device 50f of this embodiment, the trench G, which is shaped into a frame and penetrates the first planarization film 22a and the second planarization film 28a, is provided around the display region D. Such a feature can keep water from moving to the display region D through the inside of such resin layers as the first planarization film 22a and the second planarization film 28a. As a result, the organic EL layers 33 can be kept from deterioration.

Moreover, as to the organic EL display device 50f of this embodiment, the third metal layer 27h and the fourth metal layer 27i, each having a wide width, are provided to electrically and respectively connect to the first frame wire 21h and the second frame wire 21i. Such a feature can further reduce wiring resistance of the first frame wire 21h and the second frame wire 21i.

Furthermore, as to the organic EL display device 50f of this embodiment, the surface of the first planarization film 22a is covered with the protective film 23a. Such a feature can keep the surface layer of the first planarization film 22a from being etched when, for example, the second wiring layer including the power supply line 27ab is patterned by dry etching. As a result, the interior of the chamber of a dry etching apparatus can be kept from contamination.

### Other Embodiments

In the above embodiments, each organic EL layer is formed of a multilayer including such five layers as the hole-injection layer, the hole-transport layer, the light-emitting layer, the electron-transport layer, and the electron-injection layer. Alternatively, the organic EL layer may be formed of a multilayer including such three layers as a hole-injection and hole-transport layer, the light-emitting layer, and an electron-transport and electron-injection layer.

Moreover, in the organic EL display devices of the above embodiments described as examples, the first electrodes are anodes and the second electrode is a cathode. Alternatively, the present invention is applicable to an organic EL display device whose multilayered structure is inverted so that the first electrodes are cathodes and the second electrode is an anode.

Furthermore, in the organic EL display devices of the above embodiments described as examples, the electrodes of the TFTs connected to the first electrodes are drain electrodes. Alternatively, the present invention is applicable to an organic EL display device in which the electrodes of the TFTs connected to the first electrodes are referred to as source electrodes.

In addition, the display devices of the embodiments described as examples are organic EL display devices. Alternatively, the present invention is applicable to a display device including a plurality of light-emitting elements driven by a current. For example, the present invention is applicable to a display device including quantum-dot light emitting diodes (QLEDs); that is, light-emitting elements using layers containing quantum dots.

### INDUSTRIAL APPLICABILITY

As can be seen, the present invention is applicable to a flexible display device.

### REFERENCE SIGNS LIST

D Display Region
F Frame Region
G Trench
P Sub-Pixel
Sa First Slit
Sb Second Slit
T Terminal Unit
Wa First Dam Wall
Wb Second Dam Wall
10 Resin Substrate Layer (Base Substrate)
21a, 21c Source Electrode (First Wiring Layer)
21b, 21d Drain Electrode (First Wiring Layer)
21f Source Line (First Wiring Layer)
21h First Frame Wire (First Wiring Layer)
21i Second Frame Wire (First Wiring Layer)
22a First Planarization Film
23a, 23b Protective Film
24cb, 24db, 24h, 24i, 24fb Lower Metal Film
25cb, 25db, 25h, 25i, 25fb Upper Metal Film
27a Power Supply Line (Second Wiring Layer)
27c, 27cb First Metal Protruding Portion (Second Wiring Layer)
27d, 27db Second Metal Protruding Portion (Second Wiring Layer)
27e, 27eb First Metal Layer (Second Wiring Layer)
27f, 27fb Terminal Metal Layer (Second Wiring Layer)
27h Second Metal Layer (Second Wiring Layer)
27i Third Metal Layer (Second Wiring Layer)
28a Second Planarization Film
28c Inner Lower Resin Layer (First Resin Protruding Portion)
28d Outer Lower Resin Layer (Second Resin Protruding Portion)
30a, 30b, 30c, 30d TFT Layer (Thin-Film Transistor Layer)
31a First Electrode
31b Conductive Layer
32a Edge Cover
32c Inner Upper Resin Layer (Third Resin Protruding Portion)
32d Outer Upper Resin Layer (Fourth Resin Protruding Portion)
33 Light-Emitting Layer (Organic Electroluminescence (EL) Layer)
34 Second Electrode
35 Organic-EL-Element Layer (Light-Emitting-Element Layer)
36 First Inorganic Sealing Film
37 Organic Sealing Film
38 Second Inorganic Sealing Film
40 Sealing Film
50a, 50b, 50c, 50d, 50f Organic EL Display Device

1. A display device, comprising:
a base substrate;
a thin-film-transistor layer provided on the base substrate, and including a first wiring layer, a first planarization film, a second wiring layer, and a second planarization film, all of which are stacked on top of another in a stated order;
a light-emitting-element layer provided on the thin-film-transistor layer, and including a plurality of first electrodes, an edge cover, a plurality of light-emitting layers, and a second electrode, all of which are stacked on top of another in a stated order, each of the plurality of first electrodes and each of the plurality of light-emitting layers corresponding to one of a plurality of sub-pixels included in a display region, and the edge cover and the second electrode being provided in common among the plurality of sub-pixels;
a sealing film provided to cover the light-emitting-element layer, and including a first inorganic sealing film, an organic sealing film, and a second inorganic sealing film, all of which are stacked on top of another in a stated order;
a first dam wall provided in a frame region around the display region and surrounding the display region, the first dam wall being shaped into a frame to overlap with a peripheral end portion of the organic sealing film;
a power supply line provided in the display region and serving as the second wiring layer;
a first frame wire provided in the frame region and serving as the first wiring layer, the first frame wire extending to a terminal unit at an end portion of the frame region and being electrically connected to the power supply line; and
a second frame wire provided in the frame region and serving as the first wiring layer, the second frame wire extending to the terminal unit and being electrically connected to the second electrode through a conductive layer formed of a same material as, and in a same layer as, each of the first electrodes is,
wherein the first planarization film and the second planarization film include a first slit shaped into a frame, provided between the display region and the first dam wall, and penetrating the first planarization film and the second planarization film, and
in the first slit, the first frame wire and the second frame wire have respective edge portions facing each other and covered with a protective film made of an inorganic insulating film included in the thin-film transistor layer.

2. The display device according to claim 1,
wherein the protective film is provided between the first planarization film and the second wiring layer.

3. The display device according to claim 1,
wherein the protective film is provided between the first wiring layer and the first planarization film.

4. The display device according to claim 1,
wherein the first dam wall includes: a first metal protruding portion provided to electrically connect to either the first frame wire or the second frame wire, and serving as the second wiring layer; and a first resin protruding portion formed of a same material as, and in a same layer as, the second planarization film is, and provided on the first metal protruding portion.

5. The display device according to claim 4,
wherein the first metal protruding portion has an end portion shaped into a forward tapered shape so that a portion of the end portion toward the base substrate protrudes further than a portion of the end portion toward the light-emitting-element layer.

6. The display device according to claim 5,
wherein the first metal protruding portion includes: a lower metal film made of a titanium film and provided toward the base substrate; and an upper metal film made of an aluminum film and provided toward the light-emitting-element layer.

7. The display device according to claim 4,
wherein the display region is shaped into a rectangle, and
the first metal protruding portion electrically connected to the first frame wire is provided along a portion of one side, of the display region, along the terminal unit.

8. The display device according to claim 7,
wherein the first metal protruding portion electrically connected to the second frame wire is provided along: another portion of the one side, of the display region, along the terminal unit; and three sides, of the display region, not along the terminal unit.

9. The display device according to claim 4,
wherein the first dam wall includes a third resin protruding portion formed of a same material as, and in a same layer as, the edge cover is, and provided above the first resin protruding portion.

10. The display device according to claim 1, further comprising
a second dam wall shaped into a frame and provided around the first dam wall,
wherein the second planarization film includes a second slit shaped into a frame, provided between the first dam wall and the second dam wall, and penetrating the second planarization film, and
in the second slit, the first frame wire and the second frame wire have respective edge portions facing each other and covered with the protective film.

11. The display device according to claim 10,
wherein the second dam wall includes: a second metal protruding portion provided to electrically connect to either the first frame wire or the second frame wire, and serving as the second wiring layer; and a second resin protruding portion formed of a same material as, and in a same layer as, the second planarization film is, and provided on the second metal protruding portion.

12. The display device according to claim 11,
wherein the second metal protruding portion has an end portion shaped into a forward tapered shape so that a portion of the end portion toward the base substrate protrudes further than a portion of the end portion toward the light-emitting-element layer.

13. The display device according to claim 12,
wherein the second metal protruding portion includes: a lower metal film made of a titanium film and provided toward the base substrate; and an upper metal film made of an aluminum film and provided toward the light-emitting-element layer.

14. The display device according to claim 11,
wherein the display region is shaped into a rectangle, and
the second metal protruding portion electrically connected to the first frame wire is provided along a portion of one side, of the display region, along the terminal unit.

15. The display device according to claim 14,
wherein the second metal protruding portion electrically connected to the second frame wire is provided along: another portion of the one side, of the display region, along the terminal unit; and three sides, of the display region, not along the terminal unit.

16. The display device according to claim 11,
wherein the second dam wall includes a fourth resin protruding portion formed of a same material as, and in a same layer as, the edge cover is, and provided above the second resin protruding portion.

17. The display device according to claim 1,
wherein the first planarization film and the second planarization film include a trench shaped into a frame, provided between the display region and the first slit, and penetrating the first planarization film and the second planarization film.

18. The display device according to claim 17,
wherein the second electrode and the conductive layer are in contact with each other and provided inside the trench.

19. (canceled)

20. The display device according to claim 1, further comprising
a second dam wall shaped into a frame and provided around the first dam wall,
wherein the second planarization film includes a second slit shaped into a frame, provided between the first dam wall and the second dam wall, and penetrating the second planarization film,
in the second slit, the first frame wire and the second frame wire have respective edge portions facing each other and covered with the protective film,
the display device further comprises a second metal layer provided above the first frame wire, covering the first frame wire through the protective film, and electrically connected to the first frame wire,
the display device further comprises a third metal layer provided above the second frame wire, covering the second frame wire through the protective film, and electrically connected to the second frame wire,
each of the second metal layer and the third metal layer includes: a lower metal film made of a titanium film and provided toward the base substrate; and an upper metal film made of an aluminum film and provided toward the light-emitting-element layer, and
each of the second metal protruding portion and the third metal layer has an end portion shaped into a forward tapered shape so that the lower metal film protrudes further than the upper metal film.

21. The display device according to claim 1,
wherein the display region is shaped into a rectangle,
the display device includes a terminal metal layer provided between a side, of the display region, toward the terminal unit and the first slit, and electrically connected to the first frame wire, the terminal metal layer serving as the second wiring layer,
the terminal metal layer includes: a lower metal film made of a titanium film and provided toward the base substrate; and an upper metal film made of an aluminum film and provided toward the light-emitting-element layer, and
the terminal metal layer has an end portion shaped into a forward tapered shape so that the lower metal film protrudes further than the upper metal film, the end portion being covered with the second planarization film.

22. (canceled)
